(19) United States
(12) Patent Application Publication
(10) Pub. No.: US 2026/0007055 A1
(43) Pub. Date: Jan. 1, 2026

(54) Display Panel and Manufacturing Method Therefor, and Display Apparatus

(71) Applicant: BOE TECHNOLOGY GROUP CO., LTD., Chaoyang District, Beijing (CN)

(72) Inventor: Wenxiu Zhu, Beijing (CN)

(21) Appl. No.: 18/992,524

(22) PCT Filed: May 15, 2024
(86) PCT No.: PCT/CN2024/093254

§ 371 Date: Jan. 8, 2025

(30) Foreign Application Priority Data
Jun. 7, 2023 (CN) 202310676387.1

(51) Int. Cl. H10K 59/80; H10K 59/12

(52) U.S. Cl. CPC H10K 59/8792; H10K 59/1201

(57) ABSTRACT

A display panel includes a base substrate, a light-emitting unit located on a side of the base substrate, a first light blocking portion located on a side of the light-emitting unit away from the base substrate, and at least one light shielding portion located at least on a side of the first light blocking portion away from the base substrate. The base substrate includes light emission regions and a non-light emission region. The light-emitting unit includes a plurality of first light-emitting devices and a plurality of second light-emitting devices located in the light emission regions. The first light blocking portion is arranged in the non-light emission region in a direction substantially parallel to the base substrate. A light shielding portion is disposed at least between a first light-emitting device and a second light-emitting device and extends in the non-light emission region in a direction substantially perpendicular to the base substrate.

### CROSS-REFERENCE TO RELATED APPLICATIONS

This application is the United States national phase of International Patent Application No. PCT/CN2024/093254, filed May 15, 2024, and claims priority to Chinese Patent Application No. 202310676387.1, filed Jun. 7, 2023, the disclosures of which are hereby incorporated by reference in their entireties.

### BACKGROUND OF THE INVENTION

### Field of the Invention

The present disclosure relates to the field of display technologies, and in particular, to a display panel, a manufacturing method for the display panel, and a display apparatus including the display panel.

### Description of Related Art

Organic light-emitting diode (OLED) is currently a mainstream display product applied in smart display terminals due to various advantages such as self-luminous, high luminance, high contrast, high color gamut, fast response, wide viewing angle, low power consumption and flexible display.

At present, an OLED display product not only needs to have a screen sharing display state, but also needs to have a privacy protection display state. In a case where the OLED display product is used in an open scenario, the OLED display product needs to be in the screen sharing display state to share the screen; but in a case where the OLED display product is used in a scenario that requires privacy protection, the OLED display product need to be switched to be in the privacy protection display state.

### SUMMARY OF THE INVENTION

In an aspect, a display panel is provided. The display panel includes a base substrate, a light-emitting unit, a first light blocking portion and at least one light shielding portion. The base substrate includes light emission regions and a non-light emission region. The light-emitting unit is located on a side of the base substrate, and the light-emitting unit includes a plurality of first light-emitting devices and a plurality of second light-emitting devices that are located in the light emission regions. The first light blocking portion is located on a side of the light-emitting unit away from the base substrate and arranged in the non-light emission region in a first direction; the first direction is a direction substantially parallel to the base substrate. The at least one light shielding portion is located at least on a side of the first light blocking portion away from the base substrate; a light shielding portion of the at least one light shielding portion is disposed at least between a first light-emitting device of the plurality of first light-emitting devices and a second light-emitting device of the plurality of second light-emitting devices and extends in the non-light emission region in a second direction; the second direction is a direction substantially perpendicular to the base substrate.

In some embodiments, the light shielding portion is disposed at least between the first light-emitting device and the second light-emitting device that are of a same color and adjacent to each other.

In some embodiments, the at least one light shielding portion includes a plurality of light shielding portions, and the plurality of light shielding portions include a first light shielding portion and a second light shielding portion that are respectively located on two sides of the second light-emitting device; the first light shielding portion is disposed between a first light-emitting device and a second light-emitting device that are of a same color and adjacent to each other, and the second light shielding portion is disposed between another first light-emitting device and the second light-emitting device that are of different colors and adjacent to each other.

In some embodiments, a light shielding portion of the at least one light shielding portion includes a plurality of light shielding sub-portions; the plurality of light shielding sub-portions are sequentially arranged in the second direction at intervals.

In some embodiments, in the second direction, a distance between two adjacent light shielding sub-portions is greater than or equal to 1.5 μm and less than or equal to 15 μm.

In some embodiments, in the first direction, a distance between the light shielding portion and a sidewall of the second light-emitting device adjacent to the light shielding portion is less than or equal to 5 μm.

In some embodiments, an extension direction of the light shielding portion is substantially parallel to an edge of the second light-emitting device, and an extension length of the light shielding portion is greater than or equal to a length of the edge of the second light-emitting device.

In some embodiments, a light shielding portion of the at least one light shielding portion is disposed between multiple first light-emitting devices of the plurality of first light-emitting devices and multiple second light-emitting devices of the plurality of second light-emitting devices; the multiple first light-emitting devices are located on a side of the light shielding portion, and the multiple second light-emitting devices are located on another side of the light shielding portion.

In some embodiments, a light shielding portion of the at least one light shielding portion extends in the second direction toward a side of the first light blocking portion proximate to the base substrate.

In some embodiments, the display panel further includes a second light blocking portion; the second light blocking portion is located on the side of the first light blocking portion away from the base substrate; an orthographic projection of the second light blocking portion on the base substrate abuts an orthographic projection of the light shielding portion on the base substrate.

In some embodiments, the second light blocking portion is disposed on a side of the second light-emitting device in the first direction, and a light shielding portion of the at least one light shielding portion is disposed on another side of the same second light-emitting device in the first direction.

In some embodiments, the orthographic projection of the second light blocking portion on the base substrate partially overlaps with an orthographic projection of the second light-emitting device adjacent to the second light blocking portion on the base substrate; an orthographic projection of a portion of the first light blocking portion that is located in a same portion of the non-light emission region as the second light blocking portion is non-overlapping with the orthographic projection of the same second light-emitting device on the base substrate.

In some embodiments, the display panel further includes color filters; the color filters are located on the side of the light-emitting unit away from the base substrate; the color filters include a first color filter and a second color filter; the first color filter covers the first light-emitting device, and the second color filter covers the second light-emitting device; in the first direction, a dimension of the first color filter is greater than a dimension of the first light-emitting device, and a dimension of the second color filter is greater than a dimension of the second light-emitting device.

In some embodiments, the display panel further includes a pixel defining layer located on a side of the base substrate proximate to the light-emitting unit; the pixel defining layer includes a plurality of light emission openings, the plurality of first light-emitting devices and the plurality of second light-emitting devices cover the plurality of light emission openings, and a material of the pixel defining layer is a black light-blocking material.

In another aspect, a manufacturing method for a display panel is provided. The manufacturing method includes: providing a base substrate, light emission regions and a non-light emission region being defined on the base substrate; forming a light-emitting unit on a side of the base substrate, the light-emitting unit including a plurality of first light-emitting devices and a plurality of second light-emitting devices located in the light emission regions; forming a first light blocking portion on a side of the light-emitting unit away from the base substrate, the first light blocking portion being arranged in the non-light emission region in a first direction; the first direction being a direction parallel to the base substrate; and forming at least one light shielding portion on a side of the first light blocking portion away from the base substrate, a light shielding portion of the at least one light shielding portion being disposed at least between a first light-emitting device of the plurality of first light-emitting devices and a second light-emitting device of the plurality of second light-emitting devices and extending in the non-light emission region in a second direction; the second direction being a direction perpendicular to the base substrate.

In some embodiments, after forming the light-emitting unit on the side of the base substrate and before forming the first light blocking portion on the side of the light-emitting unit away from the base substrate, the manufacturing method further includes forming a portion of the light shielding portion on a side of the base substrate proximate to the light-emitting unit; forming the at least one light shielding portion on the side of the first light blocking portion away from the base substrate includes forming another portion of the light shielding portion on the side of the first light blocking portion away from the base substrate.

In some embodiments, forming the light shielding portion on the side of the first light blocking portion away from the base substrate includes: forming a planarization layer on a side of the first light blocking portion away from the base substrate; forming at least one first through hole extending in the second direction in the planarization layer, a first through hole of the at least one first through hole being disposed at least between the first light-emitting device and the second light-emitting device; and forming a light shielding portion in the first through hole.

In some embodiments, forming the light shielding portion on the side of the first light blocking portion away from the base substrate includes: forming a light shielding sub-portion on the side of the first light blocking portion away from the base substrate; and repeatedly performing the step of forming a light shielding sub-portion on the side of the first light blocking portion away from the base substrate such that a plurality of light shielding sub-portions together constitute the light shielding portion, wherein the plurality of light shielding sub-portions are sequentially stacked in the second direction.

In some embodiments, forming the light shielding portion on the side of the first light blocking portion away from the base substrate includes: forming a light shielding sub-portion on the side of the first light blocking portion away from the base substrate; forming a planarization sub-layer on a side of the light shielding sub-portion away from the base substrate; and repeatedly performing the two steps of forming a light shielding sub-portion on the side of the first light blocking portion away from the base substrate and forming a planarization sub-layer on the side of the light shielding sub-portion away from the base substrate in sequence such that a plurality of light shielding sub-portions and a plurality of planarization sub-layers are alternately arranged in the second direction, the plurality of light shielding sub-portion together constituting the light shielding portion.

In yet another aspect, a display apparatus is provided. The display apparatus includes a circuit board and the display panel according to any one of the above embodiments. The display panel is located on a side of the circuit board and coupled to the circuit board.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1A and FIG. 1B are each a structural diagram of a display apparatus having a privacy protection function, in accordance with some examples;

FIG. 2A and FIG. 2B are each a diagram showing an arrangement of sub-pixels in a display apparatus having a privacy protection function, in accordance with some examples;

FIG. 3 is a structural diagram of a display apparatus, in accordance with some embodiments;

FIG. 4 is a perspective view of a display panel, in accordance with some embodiments;

FIG. 5 is a sectional view of a display panel taken along the line A-A′ in FIG. 4, in accordance with some embodiments;

FIGS. 6A to 6C, FIG. 7, and FIG. 8 are each a diagram showing an arrangement of sub-pixels in a display panel, in accordance with some embodiments;

FIG. 9A is a sectional view of a display panel taken along the line A-A′ in FIG. 4, in accordance with some other embodiments;

FIG. 9B is a sectional view of a first light blocking portion taken along the line B-B′ in FIG. 9A;

FIG. 9C is a sectional view of a light shielding portion taken along the line C-C′ in FIG. 9A;

FIGS. 10 to 13A are each a sectional view of a display panel taken along the line A-A′ in FIG. 4, in accordance with some embodiments;

FIG. 13B is a sectional view of a light shielding portion taken along the line D-D′ in FIG. 13A;

FIGS. 14 to 18A are each a sectional view of a display panel taken along the line A-A′ in FIG. 4, in accordance with some embodiments;

FIG. 18B is a sectional view of a light shielding portion taken along the line E-E′ in FIG. 18A; and

FIGS. 19 to 23 are each a flow diagram of a manufacturing method for a display panel, in accordance with some embodiments.

### DESCRIPTION OF THE INVENTION

The technical solutions in some embodiments of the present disclosure will be clearly and completely described below in conjunction with the accompanying drawings. Obviously, the embodiments to be described are merely some but not all embodiments of the present disclosure. All other embodiments obtained by a person of ordinary skill in the art based on the embodiments of the present disclosure should belong to the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are only used for descriptive purposes, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified. As used herein, the terms “a plurality of” and “multiple” appearing herein do not indicate the same quantity.

In the description of some embodiments, the terms such as “coupled” and “connected” and derivatives thereof may be used. The term “connected” should be understood in a broad sense; for example, the term “connected” may represent a fixed connection, a detachable connection, or a one-piece connection; alternatively, it may represent a direct connection, or an indirect connection through an intermediate medium. The term “coupled” indicates that two or more components are in direct physical or electrical contact with each other. The term “coupled” or “communicatively coupled”, however, may also mean that two or more components are not in direct contact with each other, but still cooperate or interact with each other. The embodiments disclosed herein are not necessarily limited to the content herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

The term such as “about”, “substantially”, or “approximately” as used herein includes a stated value and an average value within an acceptable range of deviation of a particular value; the acceptable range of deviation may be determined, for example, by a person of ordinary skill in the art, considering measurement in question and errors (i.e., limitations of a measurement system) associated with measurement of a particular quantity.

The term such as “parallel”, “perpendicular”, or “equal” as used herein includes a stated condition and a condition similar to the stated condition within an acceptable range of deviation; the acceptable range of deviation may be determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be a deviation within ±5°; the term “perpendicular” includes absolute perpendicularity and approximate perpendicularity, and an acceptable range of deviation of the approximate perpendicularity may also be a deviation within ±5°; and the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

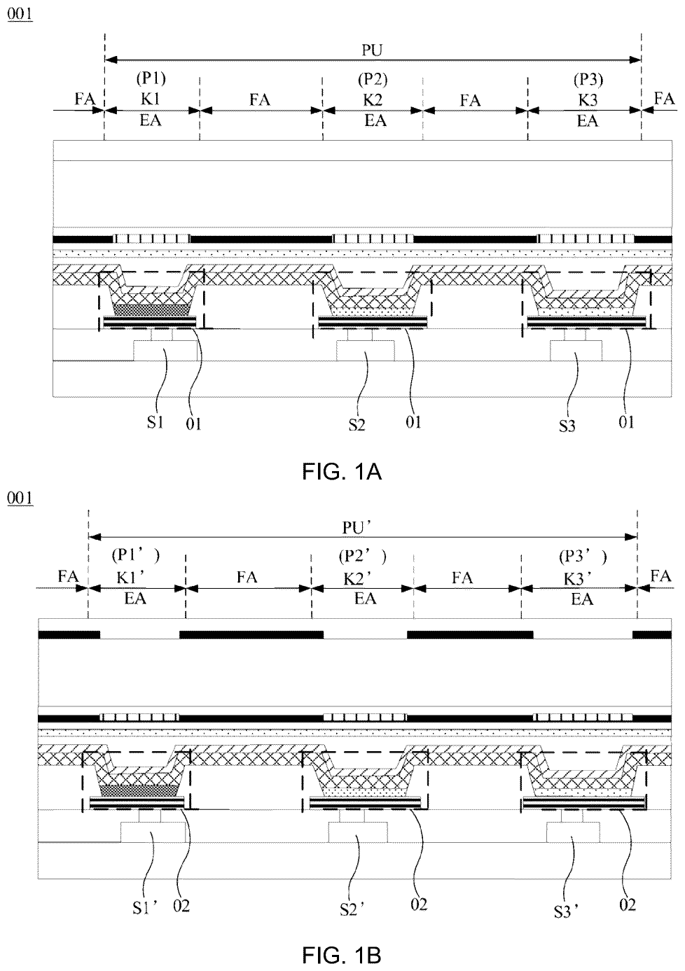

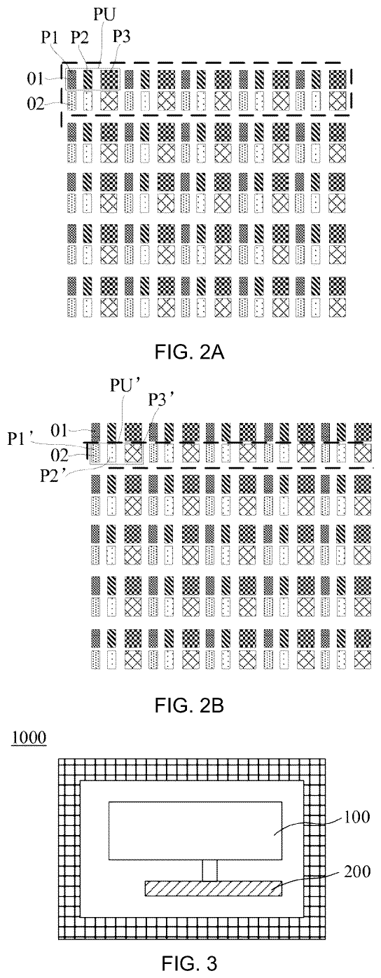

FIG. 1A and FIG. 1B are each a structural diagram of a display apparatus having a privacy protection function, in accordance with some examples; FIG. 2A and FIG. 2B are each a diagram showing an arrangement of sub-pixels in a display apparatus having a privacy protection function, in accordance with some examples.

As shown in FIGS. 1A and 1B, a display apparatus 001 having a privacy protection function includes light-emitting devices 01 for normal display and light-emitting devices 02 for privacy protection display. In a case where the display apparatus 001 having the privacy protection function is used in an open scenario, as shown in FIG. 2A, the light-emitting devices 01 for normal display and the light-emitting devices 02 for privacy protection display are both lit (i.e., multiple rows of the light-emitting devices in the region indicated by the dotted box in FIG. 2A are all lit), so that the display apparatus is in a screen sharing display state; in a case where the display apparatus 001 having the privacy protection function is used in a scenario that requires privacy protection, as shown in FIG. 2B, the light-emitting devices 01 for normal display are off and only the light-emitting devices 02 for privacy protection display are lit (i.e., only multiple rows of the light-emitting devices in the region indicated by the dotted box in FIG. 2B are lit), so that the display apparatus may be switched to be in a privacy protection display state.

However, the inventor of the present disclosure has found through researches that, in the display apparatus 001 having the privacy protection function, light with a large emission angle emitted by the light-emitting device 02 for privacy protection display is easily transmitted from two sides of the light-emitting device 02 for privacy protection display to an outside of the display apparatus, which results in a problem that the existing display apparatus 001 having the privacy protection function has a large viewing angle in the privacy protection display state and thus has a poor privacy protection effect.

In light of this, the embodiments of the present disclosure provide a display panel and a manufacturing method therefor, and a display apparatus, aiming to ameliorate the above problems. The descriptions will be made in the following separately.

FIG. 3 is a structural diagram of a display apparatus, in accordance with some embodiments.

Referring to FIG. 3, some embodiments of the present disclosure provide a display apparatus 1000. The display apparatus 1000 may be used to display static images or moving pictures. For example, the display apparatus 1000 may be a small or medium sized display apparatus such as a tablet computer, a smart phone, a head-mounted display, an automobile navigation unit, a camera, a central information display (CID) provided in a vehicle, a wristwatch-type display apparatus or other wearable device, a personal digital assistant (PDA), a portable multimedia player (PMP) and a game console, or a medium or large sized electronic apparatus such as a television, an external billboard, a monitor, a home appliance including a display screen, a personal computer and a laptop computer. The electronic apparatuses described above may represent examples of application of the display apparatus; thus, a person of ordinary skill in the art can appreciate that the display apparatus 1000 may be other electronic apparatus without departing from the spirit and scope of the present disclosure.

As shown in FIG. 3, the display apparatus 1000 may include a display panel 100 and a circuit board 200; the display panel 100 is coupled to the circuit board 200. The circuit board 200 may be located on a backlight side (i.e., a side opposite to a display side of the display panel 100) of the display panel 100. For example, the circuit board 200 may be a flexible printed circuit board (FPC) or a printed circuit board. The circuit board 200 may provide light-emitting data signals, and the display panel 100 emits light based on the light-emitting data signals provided by the circuit board 200.

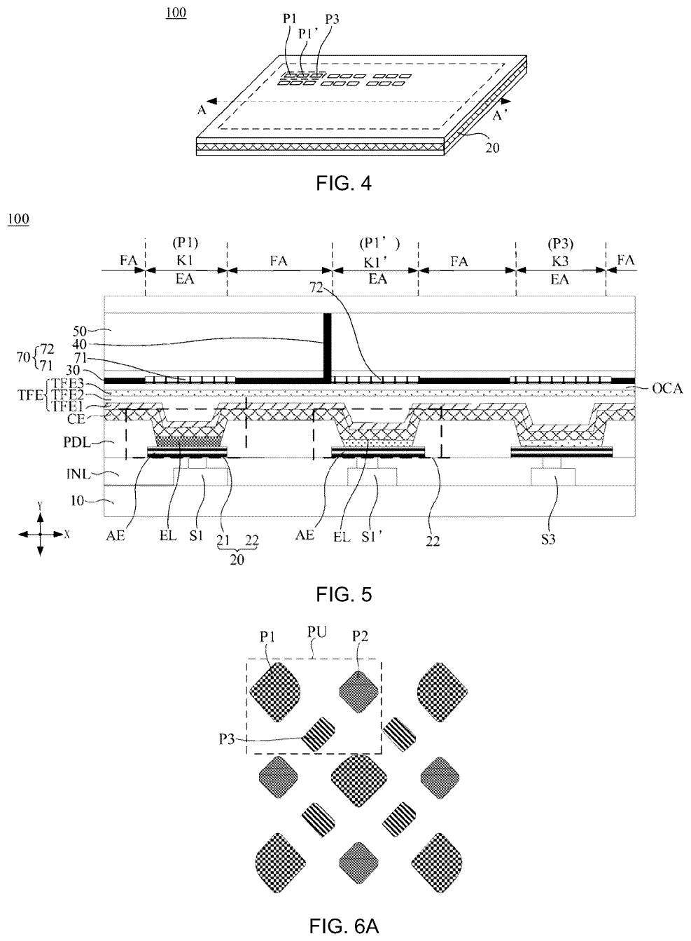

FIG. 4 is a perspective view of a display panel, in accordance with some embodiments; and FIG. 5 is a sectional view of a display panel taken along the line A-A′ in FIG. 4, in accordance with some embodiments.

Referring to FIGS. 4 and 5, some embodiments of the present disclosure provide a display panel 100. The display panel 100 is a display component capable of emitting light for displaying an image; the display panel 100 may emit single-color light (light of a single color) or colored light. The display panel 100 may be applied to the above display apparatus 1000.

In some embodiments, as shown in FIG. 5, the display panel 100 may include a base substrate 10, a light-emitting unit 20, a first light blocking portion 30 and a light shielding portion 40. The light-emitting unit 20 is located on a side of the base substrate 10, and the light-emitting unit 20 may include a plurality of light-emitting devices. The first light blocking portion 30 is disposed on a side of the light-emitting unit 20 away from the base substrate 10 and arranged in a first direction X, and the first direction X is a direction substantially parallel to the base substrate 10, i.e., parallel to a plane where the base substrate 10 is located. The light shielding portion 40 is located on a side of the base substrate 10 proximate to the light-emitting unit 20, the light shielding portion 40 extends in a second direction Y, and the second direction Y is a direction substantially perpendicular to the base substrate 10, i.e., perpendicular to the plane where the base substrate 10 is located. In a case where the light with the large emission angle emitted by the light-emitting device for privacy protection display is incident on the first light blocking portion 30 and the light shielding portion 40, the first light blocking portion 30 and the light shielding portion 40 may block and absorb the light with the large emission angle.

The base substrate 10, the light-emitting unit 20, the first light blocking portion 30, and the light shielding portion 40 of the display panel 100 will be separately described in detail below.

As shown in FIG. 5, the base substrate 10 includes light emission regions EA and a non-light emission region FA. The base substrate 10 may include a plurality of pixel unit regions PU that are repeatedly arranged. Each pixel unit region PU may include a plurality of light emission regions EA and a plurality of non-light emission regions FA.

For example, a plurality of light emission regions EA of a pixel unit region PU for normal display may include a first sub-pixel region P1, a second sub-pixel region P2 and a third sub-pixel region P3 that display different colors.

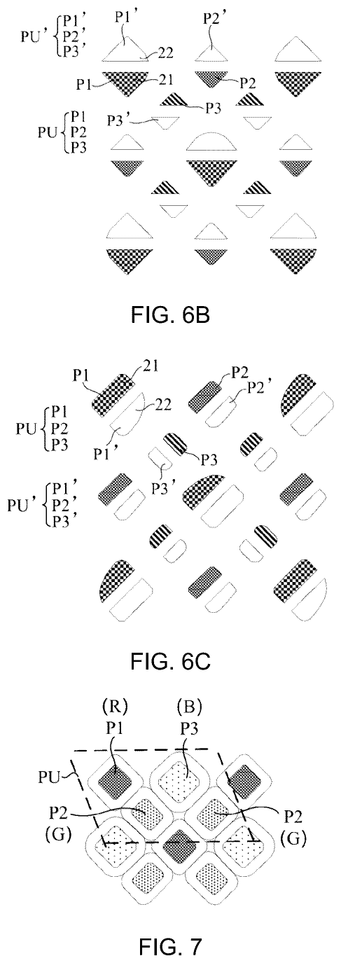

As shown in FIGS. 5 and 6B, a plurality of light emission regions EA of a pixel unit region PU′ for privacy protection display may include a first privacy protection sub-pixel region P1′, a second privacy protection sub-pixel region P2′ and a third privacy protection sub-pixel region P3′ that display different colors.

For example, the first sub-pixel region P1 and the first privacy protection sub-pixel region P1′ may be configured to emit red light, the second sub-pixel region P2 and the second privacy protection sub-pixel region P2′ may be configured to emit green light, and the third sub-pixel region P3 and the third privacy protection sub-pixel region P3′ may be configured to emit blue light.

In addition, the non-light emission region FA may be located between the first sub-pixel region P1 and the second sub-pixel region P2, between the second sub-pixel region P2 and the third sub-pixel region P3, and between the third sub-pixel region P3 and the first sub-pixel region P1. As shown in FIG. 5, the non-light emission region FA may be further located between the first sub-pixel region P1 and the first privacy protection sub-pixel region P1′.

FIGS. 6A to 6C, FIG. 7, and FIG. 8 are each a diagram showing an arrangement of sub-pixels in a display panel, in accordance with some embodiments.

In some examples, as shown in FIGS. 6A, 6B and 6C, a plurality of light emission regions EA of a pixel unit region PU may include a first sub-pixel region P1, a second sub-pixel region P2 and a third sub-pixel region P3. The first sub-pixel region P1, the second sub-pixel region P2 and the third sub-pixel region P3 may be arranged at intervals and repeatedly arranged as a whole in a direction parallel to the base substrate 10.

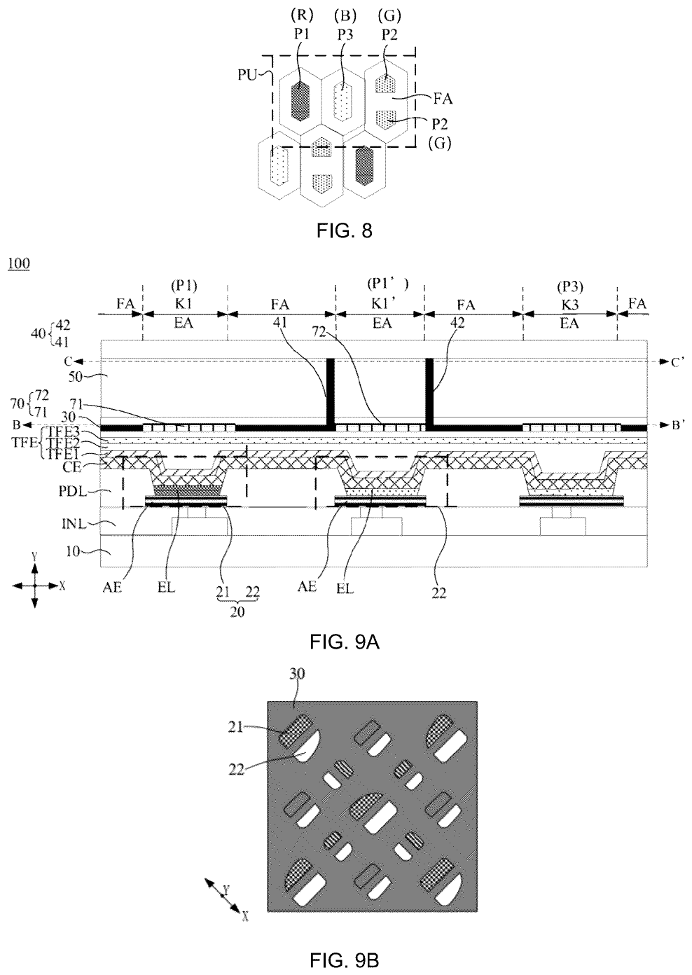

In some examples, as shown in FIGS. 7 and 8, a plurality of light emission regions EA of a pixel unit region PU may include two sub-pixel regions that display the same color, and the two sub-pixel regions displaying the same color may be adjacently arranged. For example, a pixel unit region PU includes a red sub-pixel region R, two green sub-pixel regions G and a blue sub-pixel region B, and the two green sub-pixel regions G included in the pixel unit region PU may be adjacently arranged.

In some examples, a plurality of light emission regions EA of a pixel unit region PU may include a first sub-pixel region P1, two second sub-pixel regions P2 and a third sub-pixel region P3. The first sub-pixel region P1, the two second sub-pixel regions P2 and the third sub-pixel region P3 may be arranged at intervals and are repeatedly as a whole. In this case, a non-light emission region FA may also be located between the two second sub-pixel regions P2.

It will be noted that, an arrangement of sub-pixels in a pixel unit region PU′ for privacy protection display may be the same as the arrangement of sub-pixels in the pixel unit region PU shown in FIGS. 6A to 6C and FIGS. 7 and 8, and will not be repeated here.

The base substrate 10 may be of a single-layer structure or a laminated composite structure. The base substrate 10 may be a flexible base substrate 10 or a rigid base substrate 10.

The display panel 100 may include a plurality of pixel circuits located on the base substrate 10. As shown in FIG. 1A, a first pixel circuit S1, a second pixel circuit S2 and a third pixel circuit S3 may be provided in the pixel unit region PU for normal display. For example, the first pixel circuit S1 is located in the first sub-pixel region P1, the second pixel circuit S2 is located in the second sub-pixel region P2, and the third pixel circuit S3 is located in the third sub-pixel region P3. For another example, a thin film transistor of at least one of the first pixel circuit S1, the second pixel circuit S2 and the third pixel circuit S3 may be located in the non-light emission region FA.

As shown in FIG. 1B, a first privacy protection pixel circuit S1′, a second privacy protection pixel circuit S2′ and a third privacy protection pixel circuit S3′ may be provided in the pixel unit region PU′ for privacy protection display. For example, the first privacy protection pixel circuit S1′ is located in the first privacy protection sub-pixel region P1′, the second privacy protection pixel circuit S2′ is located in the second privacy protection sub-pixel region P2′, and the third privacy protection pixel circuit S3′ is located in the third privacy protection sub-pixel region P3′. For another example, a thin film transistor of at least one of the first privacy protection pixel circuit S1′, the second privacy protection pixel circuit S2′ and the third privacy protection pixel circuit S3′ may be located in the non-light emission region FA.

There are various structures for the pixel circuit, which may be selected according to actual needs. For example, the pixel circuit may include at least two transistors (represented as T) and at least one capacitor (represented as C). For instance, the pixel circuit may have a “2T1C” structure, a “6T1C” structure, a “7T1C” structure, a “6T2C” structure, a “7T2C” structure or the like.

It will be noted that, the transistors used in the embodiments of the present disclosure may be thin film transistors, field effect transistors or other switching devices with same characteristics. Transistors of at least one of the first pixel circuit S1, the second pixel circuit S2 and the third pixel circuit S3 may include polycrystalline silicon thin film transistors or oxide semiconductor thin film transistors. For example, in the case where the transistor is a polycrystalline silicon thin film transistor, the transistor may be of a structure of a top-gate thin film transistor. The thin film transistor may be connected to signal lines, and the signal lines include but are not limited to a gate line, a data line and a power line. A gate driving sub-circuit may be connected to a pixel circuit through a gate line to provide various scanning signals; a data driving sub-circuit may be connected to the pixel circuit through a data line to provide a data signal such that the pixel circuit drives a light-emitting device to emit light.

As shown in FIG. 5, the display panel 100 may include an insulating layer INL. The insulating layer INL may be located in the first pixel circuit S1, the first privacy protection pixel circuit S1′ and the third pixel circuit S3. The insulating layer INL may have a flat surface. The insulating layer INL may be formed from an organic layer. For example, a material of the insulating layer INL may include an acrylic resin, an epoxy resin, an imide resin or an ester resin. The insulating layer INL may have through holes for exposing electrodes of the first pixel circuit S1, the second pixel circuit S2 and the third pixel circuit S3 to facilitate electrical connections.

As shown in FIG. 5, the display panel 100 may include a pixel defining layer PDL located on the base substrate 10. The pixel defining layer PDL may be formed on the insulating layer INL and defines a plurality of light emission openings.

As shown in FIG. 1A, in the pixel unit region PU for normal display, the plurality of light emission openings may include a first light emission opening K1, a second light emission opening K2 and a third light emission opening K3. The first light emission opening K1 may be located in the first sub-pixel region P1, the second light emission opening K2 may be located in the second sub-pixel region P2, and the third light emission opening K3 may be located in the third sub-pixel region P3.

As shown in FIG. 1B, in the pixel unit region PU′ for privacy protection display, the plurality of light emission openings may include a first privacy protection light emission opening K1′, a second privacy protection light emission opening K2′ and a third privacy protection light emission opening K3′. The first privacy protection light emission opening K1′ may be located in the first privacy protection sub-pixel region P1′, the second privacy protection light emission opening K2′ may be located in the second privacy protection sub-pixel region P2′, and the third privacy protection light emission opening K3′ may be located in the third privacy protection sub-pixel region P3′.

As shown in FIG. 5, the plurality of light emission openings may include a first light emission opening K1, a first privacy protection light emission opening K1′ and a third light emission opening K3. For example, the first sub-pixel region P1 may be a red light emission region, and the first privacy protection sub-pixel region P1′ may also be a red light emission region. For another example, the first sub-pixel region P1 may be a red light emission region, while the first privacy protection sub-pixel region P1′ may be a green light emission region.

As shown in FIG. 5, the light-emitting unit 20 may be located on a side of the insulating layer INL away from the base substrate 10. The plurality of light-emitting devices respectively cover the plurality of light emission openings, and the plurality of light-emitting devices are each correspondingly connected a respective pixel circuit of the plurality of pixel circuits. The plurality of light-emitting devices includes a plurality of first light-emitting devices 21 and a plurality of second light-emitting devices 22 that are both in the light emission regions EA.

The first light-emitting device 21 may be understood as a light-emitting device for normal display, and the first light-emitting device 21 is located in the pixel unit region PU for normal display. The second light-emitting device 22 may be understood as a light-emitting device for privacy protection display, and the second light-emitting device 22 is located in the pixel unit region PU′ of privacy protection display. A first light-emitting device 21 and a second light-emitting device 22 of the same color may be the same or different, which is not limited here.

The plurality of first light-emitting devices 21 may include a first red light-emitting device, a first green light-emitting device and a first blue light-emitting device. The plurality of second light-emitting devices 22 may include a second red light-emitting device, a second green light-emitting device and a second blue light-emitting device. For example, the first red light-emitting device and the second red light-emitting device may be the same or different.

In some examples, as shown in FIGS. 2A and 2B, the plurality of first light-emitting devices 21 and the plurality of second light-emitting devices 22 may be completely separated and arranged in different rows, and the colors of the first light-emitting devices 21 and the second light-emitting devices 22 in two adjacent rows may be the same.

In some other examples, as shown in FIGS. 6B and 6C, the plurality of first light-emitting devices 21 and the plurality of second light-emitting devices 22 are close to each other, and the plurality of first light-emitting devices 21 and the plurality of second light-emitting devices 22 cannot be completely separated and arranged in different rows, and multiple first light-emitting devices 21 and multiple second light-emitting devices 22 may be arranged in the same row. Colors of a first light-emitting device 21 and an adjacent second light-emitting device 22 may be the same or different.

For example, the light-emitting devices may include OLEDs, mini light-emitting devices (mini LEDs) or micro light-emitting devices (micro LEDs), which is not limited here.

In an example in which the light-emitting devices are OLEDs, as shown in FIG. 5, the OLED light-emitting device may include an anode AE, a light-emitting function layer EL, and a cathode CE that are sequentially stacked. A first light-emitting device 21 and a second light-emitting device 22 of different colors may each have an individual anode AE and light-emitting function layer EL but share the cathode CE. A first light-emitting device 21 and a second light-emitting device 22 of the same color may each have an individual anode AE but share the light-emitting function layer EL and the cathode CE. For example, a first red light-emitting device and a second red light-emitting device may each have an individual anode AE but share the light-emitting function layer EL and the cathode CE.

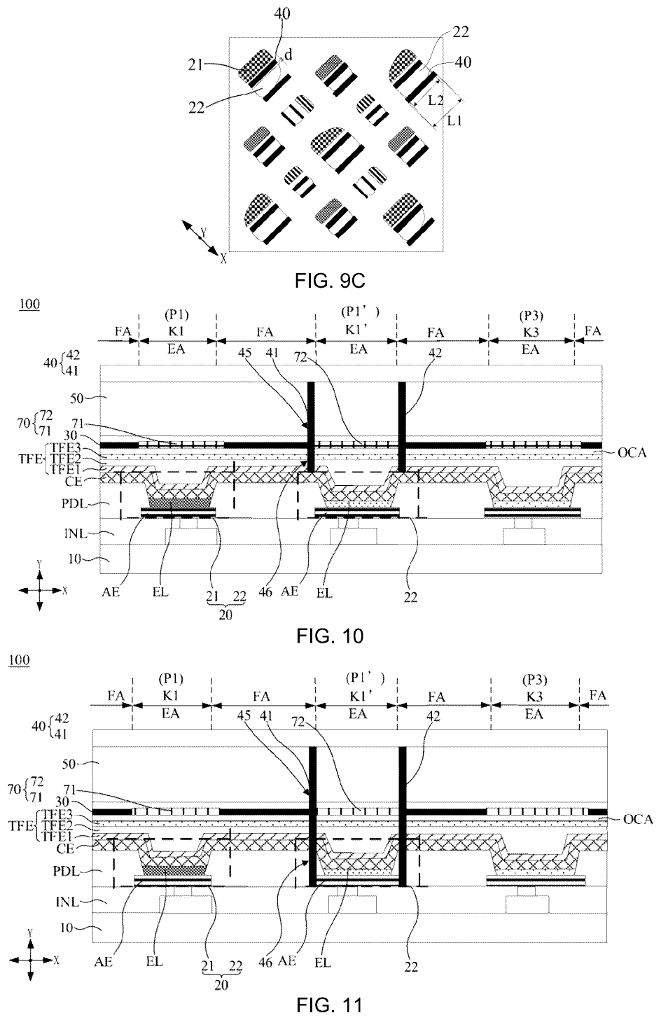

FIG. 9A is a sectional view of a display panel taken along the line A-A′ in FIG. 4, in accordance with some embodiments; FIG. 9B is a sectional view of a first light blocking portion taken along the line B-B′ in FIG. 9A; and FIG. 9C is a sectional view of a light shielding portion taken along the line C-C′ in FIG. 9A.

In some embodiments, as shown in FIGS. 5 and 9A, the display panel 100 may further include an encapsulation layer TFE. The encapsulation layer TFE may be located on a side of the light-emitting unit 20 away from the base substrate 10. The encapsulation layer TFE may be of a single-layer structure or a multi-layer composite structure. The encapsulation layer TFE is configured to block water and oxygen from entering the light-emitting unit 20.

In some examples, as shown in FIG. 9A, the encapsulation layer TFE may include a first inorganic layer TFE1, an organic layer TFE2, and a second inorganic layer TFE3 that are sequentially stacked in a direction from the light-emitting unit 20 away from the base substrate 10.

For example, in the second direction Y, a sum (a thickness of the encapsulation layer TFE) of dimensions of the first inorganic layer TFE1, the organic layer TFE2 and the second inorganic layer TFE3 is greater than or equal to 5 μm and less than or equal to 25 μm (e.g., 5 μm, 8 μm, 10 μm, 12 μm, 15 μm, 17 μm, 20 μm, 22 μm, or 25 μm).

For example, materials of the first inorganic layer TFE1 and the second inorganic layer TFE3 may be selected from at least one of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride or lithium fluoride. A material of the organic layer TFE2 may be at least one of an acrylic resin, a methacrylic resin, polyisoprene, a vinyl resin, an epoxy resin, a polyurethane resin, a cellulose resin or a perylene resin. The number of layers, the material, and the structure of the encapsulation layer TFE may be respectively changed by a person skilled in the art according to requirements, which is not limited in the present disclosure.

As shown in FIG. 5 and FIGS. 9A and 9B, the first light blocking portion 30 may be located on a side of the encapsulation layer TFE away from the base substrate 10, and the first light blocking portion 30 is arranged in the non-light emission region FA in the first direction X.

For example, a material of the first light blocking portion 30 may include a black matrix material or other black light-blocking materials.

Light with a large emission angle emitted by the second light-emitting device 22 may be incident on the first light blocking portion 30, and the first light blocking portion 30 may block and absorb the light with the large emission angle that is emitted from the second light-emitting device 22. In addition, the first light blocking portion 30 may also prevent light of different colors emitted from other light emission regions EA from entering a certain light emission region EA, so as to ensure the color purity of the light emitted from each light emission region EA to improve the color contrast of the light emitted from various light emission region EA. As a result, the display effect of the display panel 100 is improved.

As shown in FIG. 5 and FIGS. 9A and 9C, the light shielding portion(s) 40 is located at least on a side of the first light blocking portion 30 away from the base substrate 10; the light shielding portion 40 extends in the second direction Y in the non-light emission region FA. It will be understood that, in the non-light emission region FA, the light shielding portion 40 may extend in the second direction Y toward a side of the first light blocking portion 30 away from the base substrate 10, and/or the light shielding portion 40 may extend in the second direction Y toward a side of the first light blocking portion 30 proximate to the base substrate 10.

For example, in the non-light emission region FA, in a case where the light shielding portion 40 is located on one side of the first light blocking portion 30, the light shielding portion 40 may extend in the second direction Y toward the side of the first light blocking portion 30 away from the base substrate 10, or the light shielding portion 40 may extend in the second direction Y toward the side of the first light blocking portion 30 proximate to the base substrate 10.

For another example, in the non-light emission region FA, in a case where the light shielding portion 40 is located on two sides of the first light blocking portion 30, the light shielding portion 40 may extend in the second direction Y toward the side of the first light blocking portion 30 away from the base substrate 10, and the light shielding portion 40 may also extend in the second direction Y toward the side of the first light blocking portion 30 proximate to the base substrate 10.

In the first direction X, the light shielding portion 40 may be disposed on at least one side of the second light-emitting device 22. It will be understood that, the light shielding portion 40 may be disposed on one side of the second light-emitting device 22, or the light shielding portion 40 may be disposed on two sides of the second light-emitting device 22.

Light with a large emission angle emitted by the second light-emitting device 22 may be incident on the light shielding portion 40, and the light shielding portion 40 may block and absorb the light with the large emission angle that would have been transmitted from at least a side of the second light-emitting device 22 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

For example, a material of the light shielding portion 40 may include a black matrix material or other black light-blocking materials, which is not limited in the present disclosure.

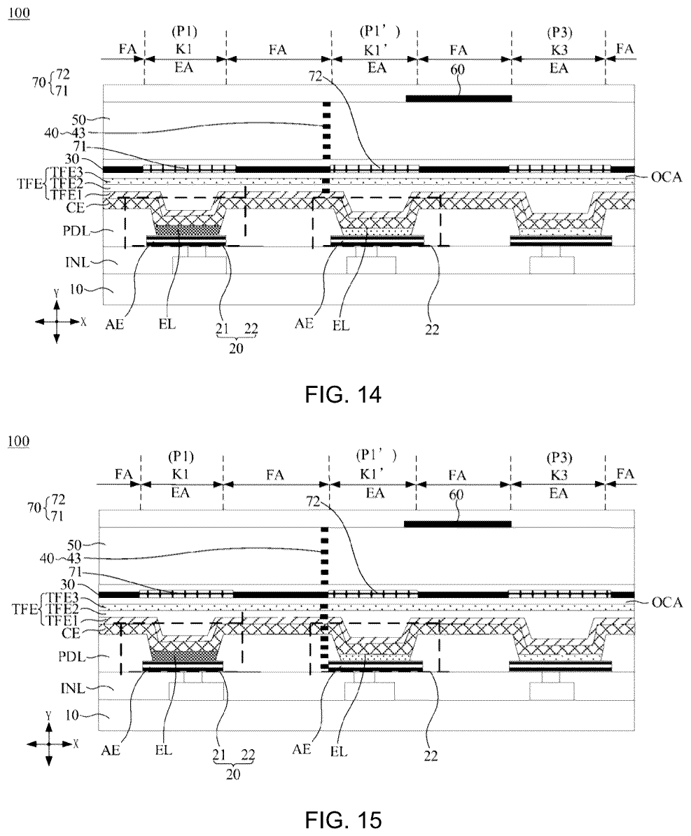

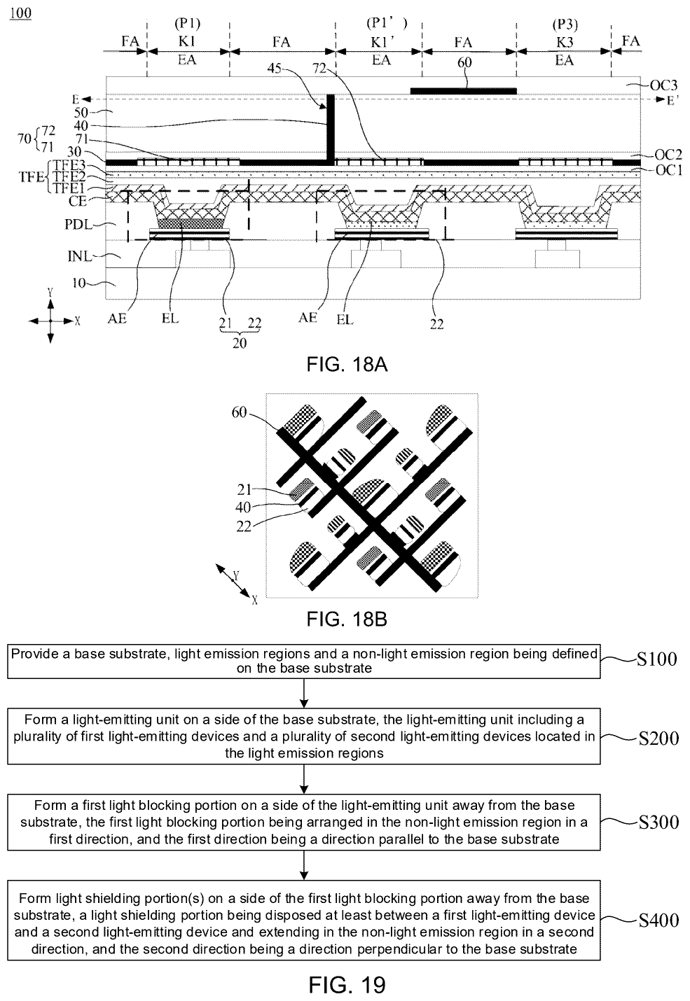

FIGS. 10 to 13A are each a sectional view of a display panel taken along the line A-A′ in FIG. 4, in accordance with some embodiments; FIG. 13B is a sectional view of a light shielding portion taken along the line D-D′ in FIG. 13A; FIGS. 14 to 18A are each a sectional view of a display panel taken along the line A-A′ in FIG. 4, in accordance with some embodiments; and FIG. 18B is a sectional view of a light shielding portion taken along the line E-E′ in FIG. 18A.

In some embodiments, in the case where the light shielding portion 40 is located on one side of the first light blocking portion 30, as shown in FIGS. 5, 9A, 13A and 18A, the light shielding portion 40 may be located on the side of the first light blocking portion 30 away from the base substrate 10.

In some examples, as shown in FIGS. 5, 9A, 13A and 18A, the display panel 100 may further include a planarization layer 50. The planarization layer 50 is located on the side of the first light blocking portion 30 away from the base substrate 10, and the planarization layer 50 extends in the first direction X. The light shielding portion 40 may extend in the second direction Y from the first light blocking portion 30 into the planarization layer 50.

As an example, a material of the planarization layer 50 may include polyimide.

Light with a large emission angle emitted by the second light-emitting device 22 may be incident on the light shielding portion 40 in the planarization layer 50, and the light shielding portion 40 may block and absorb the light with the large emission angle that would have been transmitted through the planarization layer 50 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some embodiments, as shown in FIGS. 10 to 12 and FIGS. 14 to 17, the light shielding portion 40 may extend in the second direction Y toward the side of the first light blocking portion 30 proximate to the base substrate 10.

In some examples, in the case where the light shielding portion 40 is located at one side of the first light blocking portion 30, the light shielding portion 40 may extend in the second direction Y from the first light blocking portion 30 into the encapsulation layer TFE.

In some other examples, in the case where the light shielding portion 40 is located on two sides of the first light blocking portion 30, as shown in FIGS. 10 and 14, the light shielding portion 40 may extend in the second direction Y from the planarization layer 50 into the encapsulation layer TFE.

For example, the light shielding portion 40 may extend in the second direction Y from the planarization layer 50 into the second inorganic layer TFE3 of the encapsulation layer TFE. For another example, the light shielding portion 40 may extend in the second direction Y from the planarization layer 50 into the second inorganic layer TFE3 and the organic layer TFE2 of the encapsulation layer TFE. For still another example, the light shielding portion 40 may extend in the second direction Y from the planarization layer 50 into the entire encapsulation layer TFE.

In this way, light with a large emission angle emitted by the second light-emitting device 22 may be incident on the light shielding portion 40 in the encapsulation layer TFE, and the light shielding portion 40 may block and absorb the light with the large emission angle that would have been transmitted through the encapsulation layer TFE to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, in the case where the light shielding portion 40 is located on one side of the first light blocking portion 30, the pixel defining layer PDL may be made of a semi-transmissive material, and the light shielding portion 40 may extend in the second direction Y from the first light blocking portion 30 into the pixel defining layer PDL.

In some other examples, in the case where the light shielding portion 40 is located on two sides of the first light blocking portion 30, the pixel defining layer PDL may be made of a semi-transmissive material; as shown in FIGS. 11, 15 and 17, the light shielding portion 40 may extend in the second direction Y from the planarization layer 50 into the pixel defining layer PDL.

In this way, light with a large emission angle emitted by the second light-emitting device 22 may be incident on the light shielding portion 40 in the pixel defining layer PDL, and the light shielding portion 40 in the pixel defining layer PDL may completely block and absorb the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, in the case where the light shielding portion 40 is located on one side of the first light blocking portion 30, the pixel defining layer PDL may be made of a black light-blocking material, and the light shielding portion 40 may extend in the second direction Y from the first light blocking portion 30 to a surface of the pixel defining layer PDL away from the base substrate 10.

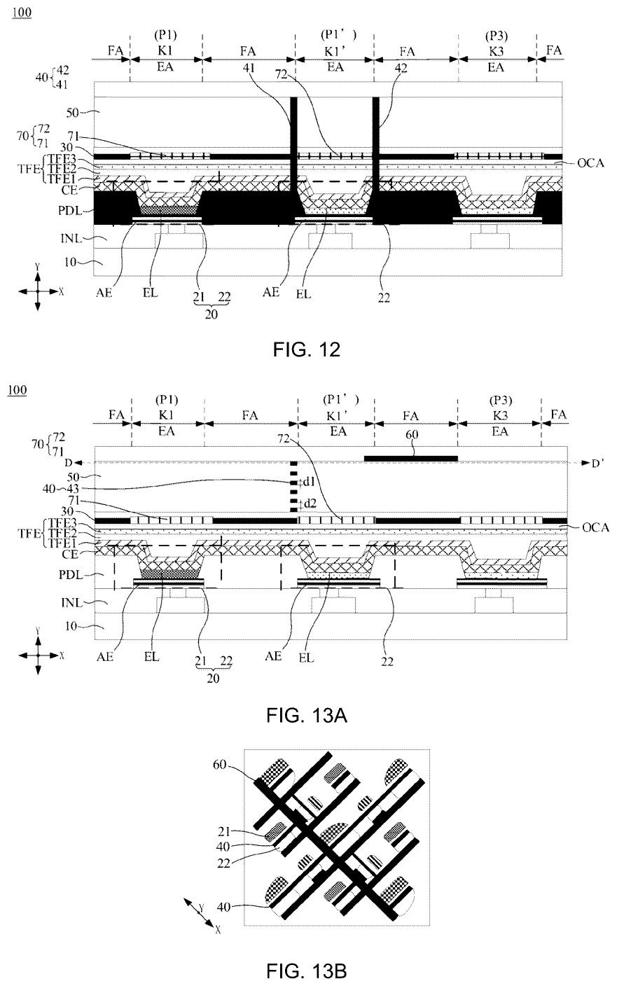

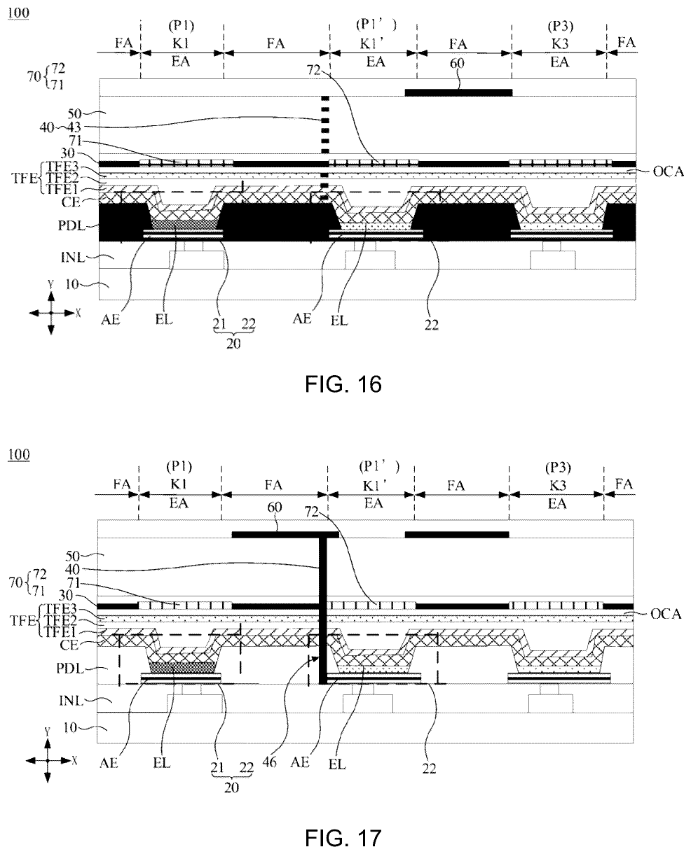

In some other examples, in the case where the light shielding portion 40 is located on two sides of the first light blocking portion 30, the pixel defining layer PDL may be made of the black light-blocking material, and as shown in FIGS. 12 and 16, the light shielding portion 40 may extend in the second direction Y from the planarization layer 50 to the surface of the pixel defining layer PDL away from the base substrate 10.

In this way, light with a large emission angle emitted by the second light-emitting device 22 may be incident on the pixel defining layer PDL and the light shielding portion 40, and the pixel defining layer PDL and the light shielding portion 40 may block and absorb the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some embodiments, as shown in FIGS. 9A, 90, 13A and 13B, a light shielding portion 40 is disposed at least between the first light-emitting device 21 and the second light-emitting device 22. It will be understood that, a light shielding portion 40 may be disposed between the first light-emitting device 21 and the second light-emitting device 22, and/or a light shielding portion 40 may be disposed between two adjacent second light-emitting devices 22 of different colors.

For example, in the case where the light shielding portion 40 is disposed on one side of the second light-emitting device 22, the light shielding portion 40 may be disposed between the first light-emitting device 21 and the second light-emitting device 22.

For another example, in the case where the light shielding portions 40 are disposed on two sides of the second light-emitting device 22, a light shielding portion 40 may be disposed between the first light-emitting device 21 and the second light-emitting device 22, and another light shielding portion 40 may be disposed between two adjacent second light-emitting devices 22 of different colors.

In this way, in a case where light with a large emission angle emitted by the second light-emitting device 22 is incident on the light shielding portion 40, the light shielding portion 40 may block and absorb the light with the large emission angle that would have been transmitted from a position between the first light-emitting device 21 and the second light-emitting device 22 to the outside of the display apparatus 1000 at least, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, as shown in FIGS. 9C and 13B, the light shielding portion 40 is disposed at least between the first light-emitting device 21 and the second light-emitting device 22 that are of the same color and adjacent to each other.

For example, in the case where the light shielding portion 40 is disposed on one side of the second light-emitting device 22, as shown in FIGS. 5 and 13A and FIGS. 14 to 18A, the light shielding portion 40 may be disposed between the first light-emitting device 21 and the second light-emitting device 22 that are of the same color and adjacent to each other.

In this way, light with a large emission angle emitted by the second light-emitting device 22 may be incident on the light shielding portion 40, and the light shielding portion 40 may block and absorb the light with the large emission angle that would have been transmitted from a position between the first light-emitting device 21 and the second light-emitting device 22 that are of the same color and adjacent to each other to the outside of the display apparatus 1000 at least, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

For example, as shown in FIG. 9C, the light shielding portion 40 may be disposed between a first light-emitting device 21 and a second light-emitting device 22 that are of different colors and adjacent to each other.

In this way, light with a large emission angle emitted by the second light-emitting device 22 may be incident on the light shielding portion 40, and the light shielding portion 40 may block and absorb the light with the large emission angle that would have been transmitted from a position between the first light-emitting device 21 and the second light-emitting device 22 that are of different colors and adjacent to each other to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

For example, in the case where the light shielding portion 40 is disposed on two sides of the second light-emitting device 22, as shown in FIG. 9A and FIGS. 10 to 12, the light shielding portions 40 include a first light shielding portion 41 and a second light shielding portion 42 that are respectively located on two sides of the second light-emitting device 22. The first light shielding portion 41 is disposed between the first light-emitting device 21 and the second light-emitting device 22 that are of the same color and adjacent to each other, and the second light shielding portion 42 is disposed between another first light-emitting device 21 and the second light-emitting device 22 that are of different colors and adjacent to each other.

In this way, light with a large emission angle emitted by the second light-emitting device 22 may be incident on the first light shielding portion 41 and the second light shielding portion 42, the first light shielding portion 41 may block and absorb light with a large emission angle that would have been transmitted from a position between the first light-emitting device 21 and the second light-emitting device 22 that are of the same color and adjacent to each other to the outside of the display apparatus 1000, and the second light shielding portion 42 may block and absorb light with a large emission angle that would have been transmitted from a position between the another first light-emitting device 21 and the second light-emitting device 22 that are of different colors and adjacent to each other to the outside of the display apparatus 1000, so that the range of light emission angle of the second light-emitting device 22 may be greatly narrowed to greatly reduce the light emission angle of the display panel 100 and the display apparatus 1000 in the privacy protection display state. As a result, the privacy protection display effect of the display panel 100 and the display apparatus 1000 is greatly improved.

In some examples, as shown in FIG. 13B, a single light shielding portion 40 may be disposed between multiple first light-emitting devices 21 and multiple second light-emitting devices 22.

The multiple first light-emitting devices 21 may be located on a side of the light shielding portion 40, and the multiple second light-emitting devices 22 may be located on another side of the light shielding portion 40. Alternatively, some of the multiple first light-emitting devices 21 and some of the multiple second light-emitting devices 22 are located on a side of the light shielding portion 40, and some other of the multiple first light-emitting devices 21 and some other of the multiple second light-emitting devices 22 are located on another side of the light shielding portion 40.

In this way, light with a large emission angle emitted by the multiple second light-emitting devices 22 may be incident on the single light shielding portion 40, and the single light shielding portion 40 may block and absorb the light with the large emission angle that would have been transmitted from a position between the multiple first light-emitting devices 21 and the multiple second light-emitting devices 22 to the outside of the display apparatus 1000, so that a single light shielding portion 40 may narrow the ranges of light emission angles of the multiple second light-emitting device 22 to reduce the light emission angle of the display panel 100 and the display apparatus 1000 in the privacy protection display state. As a result, the privacy protection display effect of the display panel 100 and the display apparatus 1000 is improved.

In some examples, as shown in FIGS. 9C, 13B and 18B, the light shielding portion 40 may be disposed between two adjacent second light-emitting devices 22 of different colors.

In this way, light with a large emission angle emitted by the two adjacent second light-emitting devices 22 of different colors may be incident on a single light shielding portion 40, and the single light shielding portion 40 may block and absorb the light with the large emission angle that would have been transmitted from a position between the two adjacent second light-emitting devices 22 of different colors to the outside of the display apparatus 1000, so that the single light shielding portion 40 may narrow the ranges of light emission angles of the two adjacent second light-emitting devices 22 of different colors to reduce the light emission angle of the display panel 100 and the display apparatus 1000 in the privacy protection display state. As a result, the privacy protection display effect of the display panel 100 and the display apparatus 1000 is improved.

In some embodiments, as shown in FIG. 9C, in the first direction X, a distance d between the light shielding portion 40 and a sidewall of the second light-emitting device 22 adjacent to the light shielding portion 40 is less than or equal to 5 μm; for example, the value of d may be 0 μm, 0.5 μm, 1 μm, 1.5 μm, 2 μm, 2.5 μm, 3 μm, 3.5 μm, 4 μm, 4.5 μm or 5 μm.

With the design in which the distance d between the light shielding portion 40 and the sidewall of the second light-emitting device 22 adjacent to the light shielding portion 40 is limited within a small range, most of the light with a large emission angle emitted by the second light-emitting device 22 may be incident on the light shielding portion 40, and the light shielding portion 40 may block and absorb the most of the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some embodiments, as shown in FIG. 9C, an extension direction of a light shielding portion 40 is substantially parallel to an edge of a second light-emitting device 22. An extension length L1 of the light shielding portion 40 is greater than or equal to a length L2 of the edge of the second light-emitting device 22. It will be understood that, in the first direction X, the length L1 of the light shielding portion 40 is greater than or equal to the length L2 of the edge of the second light-emitting device 22.

In this way, light with a large emission angle emitted by the second light-emitting device 22 may be incident on the light shielding portion 40, and the light shielding portion 40 may block and absorb all of the light with the large emission angle that would have been transmitted from the edge of the second light-emitting device 22 parallel to the light shielding portion 40 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

The light shielding portion 40 may be of a one-piece structure or a split structure. All other designs made by a person skilled in the art based on the specific shape of the light shielding portion 40 in the embodiments of the present disclosure should fall within the protection scope of the present disclosure.

In some embodiments, as shown in FIGS. 13A and 13B and FIGS. 14 to 16, the light shielding portion 40 may include a plurality of light shielding sub-portions 43, and the plurality of light shielding sub-portions 43 are sequentially arranged in the second direction Y at intervals.

For example, a shape of a section of a light block sub-unit 43 taken along the first direction X may include a rectangle, a trapezoid, a circle, an ellipse and a polygon.

For example, as shown in FIG. 13A, in the second direction Y, a dimension d1 (i.e., a thickness of the light shielding sub-portion 43) of the light shielding sub-portions 43 may be greater than or equal to 1 μm and less than or equal to 5 μm; for instance, the thickness d1 of the light shielding sub-portion 43 may be 1 μm, 1.5 μm, 2 μm, 2.5 μm, 3 μm, 3.5 μm, 4 μm, 4.5 μm or 5 μm.

In this way, light with a large emission angle emitted by the second light-emitting device 22 may be incident on the plurality of light shielding sub-portions 43, and the plurality of light shielding sub-portions 43 may block and absorb the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000. On the basis of the improvement of the privacy protection display effect of the display panel 100 and the display apparatus 1000, the plurality of light shielding sub-portions 43 may also reduce the blocking and absorption of the light for displaying images emitted by the first light-emitting device 21, thereby ensuring the screen sharing display effect of the display panel 100 and the display apparatus 1000.

In some examples, as shown in FIG. 13A, in the second direction Y, a distance d2 between two adjacent light shielding sub-portions 43 may be greater than or equal to 1.5 μm and less than or equal to 15 μm. For example, the distance d2 between two adjacent light shielding sub-portions 43 may be 1.5 μm, 2 μm, 3 μm, 5 μm, 7 μm, 8 μm, 9 μm, 10 μm, 12 μm, 14 μm or 15 μm. The distance d2 between two adjacent light shielding sub-portions 43 and the thickness d1 of the light shielding sub-portion 43 may be the same or different, which is not limited here.

On the basis that the plurality of light shielding sub-portions 43 may improve the privacy protection display effect of the display panel 100 and the display apparatus 1000, by limiting the distance d2 between two adjacent shielding sub-portions 43 within a proper range, the blocking and absorption of the light for displaying images emitted by the first light-emitting device 21 by the plurality of light shielding sub-portions 43 may be greatly reduced, thereby well ensuring the screen sharing display effect of the display panel 100 and the display apparatus 1000.

In some examples, as shown in FIG. 13A and FIGS. 14 to 16, the plurality of light shielding sub-portions 43 may extend in the second direction Y from the first light blocking portion 30 into the planarization layer 50. The planarization layer 50 may include a plurality of planarization sub-layers (not shown in the figures), and the plurality of planarization sub-layers and the plurality of light shielding sub-portions 43 are alternately stacked in sequence in the second direction Y.

For example, the thickness d1 of the light shielding sub-portion 43 and a dimension (i.e., a thickness of the planarization sub-layer) of the planarization sub-layer in the second direction Y may be the same or different, which is not limited here.

In this way, the plurality of light shielding sub-portions 43 may block and absorb the light with a large emission angle that would have been transmitted through the planarization layer 50 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, as shown in FIG. 14, the plurality of light shielding sub-portions 43 may extend in the second direction Y from the planarization layer 50 into the encapsulation layer TFE. For example, the plurality of light shielding sub-portions 43 may extend in the second direction Y from the planarization layer 50 into the second inorganic layer TFE3 of the encapsulation layer TFE. For another example, the plurality of light shielding sub-portions 43 may extend in the second direction Y from the planarization layer 50 into the second inorganic layer TFE3 and the organic layer TFE2 of the encapsulation layer TFE. For still another example, the plurality of light shielding sub-portions 43 may extend in the second direction Y from the planarization layer 50 into the entire encapsulation layer TFE.

In this way, the plurality of light shielding sub-portions 43 may block and absorb the light with a large emission angle that would have been transmitted to the outside of the display apparatus 1000 through the planarization layer 50 and the encapsulation layer TFE, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, as shown in FIG. 15, the plurality of light shielding sub-portions 43 may extend in the second direction Y from the planarization layer 50 into the pixel defining layer PDL.

In this way, the plurality of light shielding sub-portions 43 in the planarization layer 50 and the pixel defining layer PDL may block and absorb the light with a large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, as shown in FIG. 16, the pixel defining layer PDL may be made of a black light-blocking material, and the plurality of light shielding sub-portions 43 may extend in the second direction Y from the planarization layer 50 to a surface of the pixel defining layer PDL away from the base substrate 10.

In this way, the pixel defining layer PDL and the plurality of light block sub-units 43 in the planarization layer 50 may block and absorb the light with a large emission angle that would otherwise be transmitted to the outside of the display apparatus 1000, which may narrow the range of light emission angle of the second light-emitting device 22 to reduce the light emission angles of the display panel 100 and the display apparatus 1000 in the privacy protection display state, thereby improving the privacy protection display effect of the display panel 100 and the display apparatus 1000.

In some embodiments, as shown in FIG. 13A and FIGS. 14 to 18A, the display panel 100 may further include a second light blocking portion 60. The second light blocking portion 60 may be located on a side of the first light blocking portion 30 away from the base substrate 10. An orthographic projection of the second light blocking portion 60 on the base substrate 10 abuts an orthographic projection of the light shielding portion 40 on the base substrate 10.

For example, as shown in FIG. 13A and FIGS. 14 to 18A, the second light blocking portion 60 may be located on a surface of the planarization layer 50 away from the base substrate 10.

For example, a dimension (i.e., a thickness of the second light blocking portion 60) of the second light blocking portion 60 in the second direction Y may be greater than or equal to 2 μm and less than or equal to 6 μm (e.g., 2 μm, 2.5 μm, 3 μm, 3.5 μm, 4 μm, 4.5 μm, 5 μm, 5.5 μm, or 6 μm).

A material of the second light blocking portion 60 may include a black matrix material or other black light-blocking materials. The material of the second light blocking portion 60 may be the same as or different from the material of the first light blocking portion 30, which is not limited here.

In this way, light with a large emission angle emitted by the second light-emitting device 22 may be incident on the second light blocking portion 60, and the second light blocking portion 60, in combination with the first light blocking portion 30 and the light shielding portion 40, may block and absorb the light with the large emission angle that would have been transmitted to the outside of the display apparatus 1000 from other regions except the light emission region EA where the second light-emitting device 22 is located, so that the range of light emission angle of the second light-emitting device 22 is narrowed as much as possible to reduce the light emission angle of the display panel 100 and the display apparatus 1000 in the privacy protection display state, thereby improving the privacy protection display effect of the display panel 100 and the display apparatus 1000.

In some examples, as shown in FIG. 17, the second light blocking portion 60 and the light shielding portion 40 may be disposed on a same side of the second light-emitting device 22 in the first direction X.

Thus, light with a large emission angle emitted by the second light-emitting device 22 may be incident on the second light blocking portion 60 and the light shielding portion 40, and the second light blocking portion 60 and the light shielding portion 40 may block and absorb the light with the large emission angle that would have been transmitted from a side of the second light-emitting device 22 to the outside of the display apparatus 1000, which may narrow the range of light emission angle of the second light-emitting device 22 to reduce the light emission angles of the display panel 100 and the display apparatus 1000 in the privacy protection display state, thereby improving the privacy protection display effect of the display panel 100 and the display apparatus 1000.

In some other examples, as shown in FIG. 18A, the second light blocking portion 60 may be disposed on a side of the second light-emitting device 22 in the first direction X, and the light shielding portion 40 may be disposed on another side of the same second light-emitting device 22 in the first direction X.

Light with a large emission angle emitted by the second light-emitting device 22 may be incident on the second light blocking portion 60 and the light shielding portion 40, the second light blocking portion 60 may block and absorb light with a large emission angle that would have been transmitted from a side of the second light-emitting device 22 to the outside of the display apparatus 1000, and the light shielding portion 40 may block and absorb light with a large emission angle that would have been transmitted from another side of the second light-emitting device 22 to the outside of the display apparatus 1000, so that the range of light emission angle of the second light-emitting device 22 may be greatly narrowed to greatly reduce the light emission angle of the display panel 100 and the display apparatus 1000 in the privacy protection display state. As a result, the privacy protection display effect of the display panel 100 and the display apparatus 1000 is greatly improved.

In some examples, as shown in FIG. 13A and FIGS. 14 to 18A, the orthographic projection of the second light blocking portion 60 on the base substrate 10 partially overlaps with an orthographic projection of a second light-emitting device 22 adjacent to the second light blocking portion 60 on the base substrate 10. An orthographic projection, on the base substrate 10, of a portion of the first light blocking portion 30 that is located in the same portion of non-light emission region FA as the second light blocking portion 60 is non-overlapping with the orthographic projection of the same second light-emitting device 22 on the base substrate 10. It will be understood that, the second light blocking portion 60 is located in the non-light emission region FA, and the second light blocking portion 60 may also partially extend into a light emission region EA where the adjacent second light-emitting device 22 is located. The first light blocking portion 30 located in the same non-light emission region FA as the second light blocking portion 60 is located only in the non-light emission region FA.

For example, in the first direction X, a dimension of the second light blocking portion 60 is greater than a dimension of the first light blocking portion 30 located in the same non-light emission region FA as the second light blocking portion 60, and a difference in dimension between the second light blocking portion 60 and the first light blocking portion 30 located in the same non-light emission region FA is greater than or equal to 2 μm and less than or equal to 8 μm (e.g., 2 μm, 2.5 μm, 3 μm, 4 μm, 4.5 μm, 5 μm, 6 μm, 7 μm, or 8 μm).

The orthographic projection of the second light blocking portion 60 on the base substrate 10 may cover the orthographic projection of the first light blocking portion 30 located in the same non-light emission region FA as the second light blocking portion 60 on the base substrate 10.

In this way, the second light blocking portion 60 may block and absorb more of the light with a large emission angle emitted by the second light-emitting device 22 that would have been transmitted to the outside of the display apparatus 1000, which may further narrow the range of light emission angle of the second light-emitting device 22 to further reduce the light emission angle of the display panel 100 and the display apparatus 1000 in the privacy protection display state, thereby further improving the privacy protection display effect of the display panel 100 and the display apparatus 1000. On the basis of the improvement of the privacy protection display effect of the display panel 100 and the display apparatus 1000, the first light blocking portion 30 does not block light for normal display emitted from the light emission region EA where the second light-emitting device 22 is located, which may ensure the display effect of the second light-emitting device 22, thereby ensuring the display effect of the display panel 100 and the display apparatus 1000.

In some embodiments, as shown in FIGS. 5 and 9A, FIGS. 10 to 13A and FIGS. 14 to 18A, the display panel 100 may further include color filters 70. The color filters 70 may be located on a side of the light-emitting units 20 away from the base substrate 10. The color filters 70 may include a first color filter 71 and a second color filter 72.

The first color filter 71 covers the first light-emitting device 21, and the second color filter 72 covers the second light-emitting device 22. It will be understood that, an orthographic projection of the first color filter 71 on the base substrate 10 covers the orthographic projection of the first light-emitting device 21 on the base substrate 10; an orthographic projection of the second color filter 72 on the base substrate 10 covers the orthographic projection of the second light-emitting device 22 on the base substrate 10.

In the first direction X, a dimension of the first color filter 71 is greater than a dimension of the first light-emitting device 21, and a dimension of the second color filter 72 is substantially equal to a dimension of the second light-emitting device 22. It will be understood that, in the first direction X, in a case where the dimension of the first light-emitting device 21 is the same as the dimension of the second light-emitting device 22, the dimension of the first color filter 71 is greater than the dimension of the second color filter 72.

The color filter 70 may reduce the reflection of light for displaying images emitted by the light-emitting device and filter out the undesired color in the light for displaying images to improve the light emission efficiency of the display panel 100 and the saturation of the light for displaying images, thereby improving the display effect of the display apparatus 1000. In the first direction X, the dimension of the first color filter 71 is limited to be greater than the dimension of the first light-emitting device 21, which may improve the light emission efficiency of the first light-emitting device 21, thereby improving the display effect of the display apparatus 1000 in the screen sharing display state. In the first direction X, the dimension of the second color filter 72 is limited to be substantially equal to the dimension of the second light-emitting device 22, which may improve the light emission efficiency of the second light-emitting device 22 on the basis that the range of light emission angle of the second light-emitting device 22 is ensured to be small, thereby improving the display effect of the display apparatus 1000 in the privacy protection display state.

In some examples, as shown in FIGS. 5 and 9A, FIGS. 10 to 13A and FIGS. 14 to 18A, the color filter 70 may be disposed in the same layer as the first light blocking portion 30. It will be understood that, an orthographic projection of the color filter 70 on a plane perpendicular to the base substrate 10 may at least partially overlap with an orthographic projection of the first light blocking portion 30 on the plane perpendicular to the base substrate 10.

In this way, the display apparatus 1000 may be thinned on the basis of the improvement in the display effect of the display apparatus 1000.

In some examples, the display panel 100 may further include a touch layer (not shown in the figures) located in the non-light emission region FA. The touch layer may be located on a side of the encapsulation layer TFE away from the base substrate 10. The touch layer may include a single metal layer or multiple metal layers. The metal layer(s) of the touch layer may be located on a side of the encapsulation layer TFE proximate to the first light blocking portion 30. The metal layer(s) in the touch layer may be disposed in the same layer as the color filter 70. It will be understood that, orthographic projection of the metal layer in the touch layer on the plane perpendicular to the base substrate 10 may at least partially overlap with the orthographic projection of the color filter 70 on the plane perpendicular to the base substrate 10.

In this way, the display apparatus 1000 having a touch function may be thinned on the basis of the improvement in the display effect of the display apparatus 1000 having the touch function.

It will be noted that, in the display panel 100 and the display apparatus 1000 provided in the embodiments of the present disclosure, the encapsulation layer TFE and the touch layer may have an optically clear adhesive (OCA) layer provided therebetween, the first light blocking portion 30 and the planarization layer 50 may have an optically clear adhesive layer provided therebetween, and the surface of the planarization layer 50 away from the base substrate 10 and an adjacent functional layer may also have an optically clear adhesive layer provided therebetween, which is not limited here.

For example, as shown in FIG. 18A, these optically clear adhesive layers may include a first optically clear adhesive layer OC1, a second optically clear adhesive layer OC2 and a third optically clear adhesive layer OC3. The first optically clear adhesive layer OC1 may be disposed between the encapsulation layer TFE and the touch layer, and a dimension in the second direction Y of the first optically clear adhesive layer OC1 may be greater than or equal to 2 μm and less than or equal to 6 μm (e.g., 2 μm, 2.5 μm, 3 μm, 3.5 μm, 4 μm, 4.5 μm, 5 μm, 5.5 μm, or 6 μm). The second optically clear adhesive layer OC2 may be disposed between the color filter 70 and the planarization layer 50, and a dimension in the second direction Y of the second optically clear adhesive layer OC2 may be greater than or equal to 3 μm and less than or equal to 8 μm (e.g., 3 μm, 3.5 μm, 4 μm, 4.5 μm, 5 μm, 5.5 μm, 6 μm, 7 μm or 8 μm). The third optically clear adhesive layer OC3 may be disposed on the surface of the planarization layer 50 away from the base substrate 10, and a dimension in the second direction Y of the third optically clear adhesive layer OC3 may be determined according to actual needs.

In summary, in the display panel 100 and the display apparatus 1000 provided by the embodiments of the present disclosure, light with a large emission angle emitted by the second light-emitting device 22 may be incident on the first light blocking portion 30 and the light shielding portion 40, and the first light blocking portion 30 and the light shielding portion 40 may block and absorb the light with the large emission angle that would have been transmitted from the second light-emitting device 22 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000. Furthermore, the first light blocking portion 30 may also prevent light of different colors emitted from other light emission regions EA from entering a certain light emission region EA, so as to ensure the color purity of the light emitted from each light emission region EA and improve the color contrast of the light emitted from each light emission region EA. As a result, the display effect of the display panel 100 and the display apparatus 1000 is improved.

FIGS. 19 to 23 are each a flow diagram of a manufacturing method for a display panel, in accordance with some embodiments.

As shown in FIG. 19, embodiments of the present disclosure provide a manufacturing method for a display panel 100, and the manufacturing method may include step S100 to step S400.

In the step S100, a base substrate 10 is provided; the base substrate 10 includes light emission regions EA and a non-light emission region FA. Detailed description of the structural features of the base substrate 10 may refer to the above and will not be repeated here.

The base substrate 10 may be a rigid base substrate 10 or a flexible base substrate 10. For example, a material of the base substrate 10 may be polyethylene terephthalate (PET), polyimide (PI), or cyclo olefin polymer (COP).

For example, in a mini LED display substrate, the base substrate 10 may be a glass substrate or a printed circuit board (PCB) substrate.

After the step S100, a plurality of pixel circuits may be formed on the base substrate 10. Detailed description of the plurality of pixel circuits may refer to the above and will not be repeated here.

After the plurality of pixel circuits are formed, an insulating layer INL covering the plurality of pixel circuits may be formed. Detailed description of the insulating layer INL may refer to the above and will not be repeated here.

In the step S200, a light-emitting unit 20 is formed on a side of the base substrate 10.

As shown in FIG. 5, the light-emitting unit 20 includes a plurality of light-emitting devices. The plurality of light-emitting devices respectively cover a plurality of light emission openings, and the plurality of light-emitting devices are each connected to a respective pixel circuit of the plurality of pixel circuits. The plurality of light-emitting devices may include a plurality of first light-emitting devices 21 and a plurality of second light-emitting devices 22 located in the light emission regions EA.

The first light-emitting device 21 may be understood as a light-emitting device for normal display, and the second light-emitting device 22 may be understood as a light-emitting device for privacy protection display. A first light-emitting device 21 and a second light-emitting device 22 of the same color may be the same or different, which is not limited here.

For example, the light-emitting devices may include OLEDs, mini light-emitting devices (mini LEDs) or micro light-emitting devices (micro LEDs), which is not limited here.

In an example in which the light-emitting devices are OLEDs, as shown in FIG. 5, the OLED light-emitting device may include an anode AE, a light-emitting function layer EL, and a cathode CE that are sequentially stacked. The step S200 may include: forming anodes AE on a side of the insulating layer INL away from the base substrate 10 by deposition, exposure, development and etching; next, forming a pixel defining layer PDL on a side of the anodes away from the base substrate 10; the pixel defining layer PDL is provided with a plurality of light emission openings, and the light emission openings expose the anodes AE; then, forming the light-emitting function layer EL covering the light emission openings; and then, forming the cathode CE on a side of the light-emitting function layer EL away from the anodes AE.

A first light-emitting device 21 and a second light-emitting device 22 of different colors may each have an individual anode AE and light-emitting function layer EL but share the cathode CE. A first light-emitting device 21 and a second light-emitting device 22 of the same color may each have an individual anode AE but share the light-emitting function layer EL and the cathode CE. For example, a first red light-emitting device and a second red light-emitting device may each have an individual anode AE but share the light-emitting function layer EL and the cathode CE.

In some examples, as shown in FIGS. 5 and 9A, the display panel 100 may further include an encapsulation layer TFE. The encapsulation layer TFE may be of a single-layer structure or a multi-layer composite structure. Detailed description of the structural features and material of the encapsulation layer TFE may refer to the above and will not be repeated here.

For example, the encapsulation layer TFE may include a first inorganic layer TFE1, an organic layer TFE2, and a second inorganic layer TFE3 that are sequentially stacked in the direction from the light-emitting unit 20 away from the base substrate 10. After the step S200, the first inorganic layer TFE1 may be formed by deposition on a side of the light-emitting unit 20 away from the base substrate 10; next, the organic layer TFE2 may be formed by deposition on a side of the first inorganic layer TFE1 away from the base substrate 10; and then, the second inorganic layer TFE3 may be formed by deposition on a side of the organic layer TFE2 away from the first inorganic layer TFE1.

In the step S300, a first light blocking portion 30 is formed on the side of the light-emitting unit 20 away from the base substrate 10. The first light blocking portion 30 is arranged in the non-light emission region FA in the first direction X, and the first direction X is a direction parallel to the base substrate 10.

In some examples, as shown in FIGS. 5, 9A and 10, the step S300 may include: forming a whole layer of first light blocking portion material layer on a side of the encapsulation layer TFE away from the base substrate 10 by coating; then, removing portions of the first light blocking portion material layer located in the light emission regions EA by exposure and development to retain a portion of the first light blocking portion material layer in the non-light emission layer FA as the first light blocking portion 30.

For example, the material of the first light blocking portion 30 may include a black matrix material or other black light-blocking materials.

Light with a large emission angle emitted by the second light-emitting device 22 may be incident on the first light blocking portion 30, and the first light blocking portion 30 may block and absorb the light with the large emission angle that is emitted from the second light-emitting device 22. In addition, the first light blocking portion 30 may also prevent light of different colors emitted from other light emission regions EA from entering a certain light emission region EA, so as to ensure the color purity of the light emitted from each light emission region EA and improve the color contrast of the light emitted from each light emission region EA. As a result, the display effect of the display panel 100 is improved.

In the step S400, light shielding portion(s) 40 is formed on a side of the first light blocking portion 30 away from the base substrate 10. A light shielding portion 40 is disposed at least between a first light-emitting device 21 and a second light-emitting device 22, and extends in the second direction Y in the non-light emission region FA. The second direction Y is a direction perpendicular to the base substrate 10.

For example, the material of the light shielding portion 40 may be a black matrix material or other black light-blocking materials, which is not limited in the present disclosure.

In some embodiments, as shown in FIGS. 5, 9A, 13A and 18A, the light shielding portion 40 may be located on a side of the first light blocking portion 30 away from the base substrate 10.

The display panel 100 may further include a planarization layer 50. The planarization layer 50 is located on the side of the first light blocking portion 30 away from the base substrate 10, and the planarization layer 50 extends in the first direction X. The light shielding portion 40 may extend in the second direction Y from the first light blocking portion 30 into the planarization layer 50.

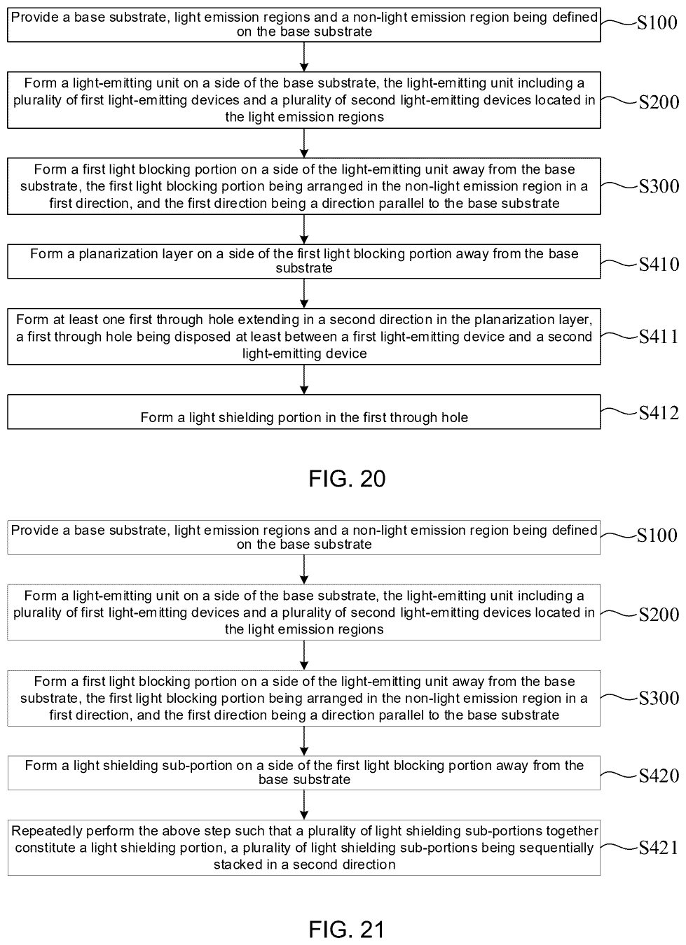

In the second direction Y, the light shielding portion 40 may be of a one-piece structure formed by a single patterning process. As shown in FIGS. 18A and 20, the step S400 may include step S410 to step S412.

In the step S410, the planarization layer 50 is formed on the side of the first light blocking portion 30 away from the base substrate 10.

For example, the step S410 may include: forming the planarization layer 50 on the side of the first light blocking portion 30 away from the base substrate 10 by inkjet printing and curing.

In the step S411, at least one first through hole 45 extending in the second direction Y is formed in the planarization layer 50. A first through hole 45 is disposed at least between the first light-emitting device 21 and the second light-emitting device 22.

For example, a shape of a section of the first through hole 45 along the first direction X may be a rectangle, a trapezoid, a circle, an ellipse, or a polygon.

In some examples, the step S411 may include: forming the at least one first through hole 45 extending in the second direction Y in the planarization layer 50 by etching.

The first through hole 45 is disposed at least between a first light-emitting device 21 and a second light-emitting device 22 that are of the same color and adjacent to each other.

For example, a first through hole 45 may be disposed between a first light-emitting device 21 and a second light-emitting device 22 that are of the same color and adjacent to each other.

For another example, another first through hole 45 may be disposed between a first light-emitting device 21 and a second light-emitting device 22 that are of different colors and adjacent to each other.

For example, a single first through hole 45 may be disposed between multiple first light-emitting devices 21 and multiple second light-emitting devices 22. The multiple first light-emitting devices 21 may be located on a side of the first through hole 45, and the multiple second light-emitting devices 22 may be located on another side of the first through hole 45. Alternatively, some of the multiple first light-emitting devices 21 and some of the multiple second light-emitting devices 22 are located on a side of the first through hole 45, and some other of the multiple first light-emitting devices 21 and some other of the multiple second light-emitting devices 22 are located on another side of the first through hole 45.

For example, in the step S411, two first through holes 45 both extending in the second direction Y are formed in the planarization layer 50. The two first through holes 45 are respectively disposed on two sides of the second light-emitting device 22. One of the first through holes 45 may be disposed between a first light-emitting device 21 and the second light-emitting device 22 that are of the same color and adjacent to each other, and the other first through hole 45 may be disposed between another first light-emitting device 21 and the second light-emitting device 22 that are of different colors and adjacent to each other.

In the step S412, the light shielding portion 40 is formed in the first through hole 45. For example, the step S412 may include: forming the light shielding portion 40 in the first through hole 45 by coating.

In this way, the process of forming the light shielding portion(s) 40 is relatively simple, which may simplify the manufacturing process of the display panel 100 and the display apparatus 1000. Light with a large emission angle emitted by the second light-emitting device 22 may be incident on the light shielding portion 40 in the planarization layer 50, and the light shielding portion 40 may block and absorb the light with the large emission angle that would have been transmitted to the outside of the display apparatus 1000 through the planarization layer 50, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some embodiments, as shown in FIGS. 9A, 90, 13A and 13B, the light shielding portion 40 is disposed at least between the first light-emitting device 21 and the second light-emitting device 22. It will be understood that, a light shielding portion 40 may be disposed between the first light-emitting device 21 and the second light-emitting device 22, and/or a light shielding portion 40 may be disposed between two adjacent second light-emitting devices 22 of different colors.

For example, in the case where the light shielding portion 40 is disposed on one side of the second light-emitting device 22, the light shielding portion 40 may be disposed between the first light-emitting device 21 and the second light-emitting device 22.

For another example, in the case where the light shielding portions 40 are disposed on two sides of the second light-emitting device 22, a light shielding portion 40 may be disposed between the first light-emitting device 21 and the second light-emitting device 22, and another light shielding portion 40 may be disposed between two adjacent second light-emitting devices 22 of different colors.

In this way, in a case where light with a large emission angle emitted by the second light-emitting device 22 is incident on the light shielding portion 40, the light shielding portion 40 may block and absorb the light with the large emission angle that would have been transmitted from a position between the first light-emitting device 21 and the second light-emitting device 22 to the outside of the display apparatus 1000 at least, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, as shown in FIGS. 9C and 13B, the light shielding portion 40 is disposed at least between the first light-emitting device 21 and the second light-emitting device 22 that are of the same color and adjacent to each other.

For example, in the case where the light shielding portion 40 is disposed on one side of the second light-emitting device 22, as shown in FIGS. 5 and 13A and FIGS. 14 to 18A, the light shielding portion 40 may be disposed between the first light-emitting device 21 and the second light-emitting device 22 that are of the same color and adjacent to each other.

In this way, light with a large emission angle emitted by the second light-emitting device 22 may be incident on the light shielding portion 40, and the light shielding portion 40 may block and absorb the light with the large emission angle that would have been transmitted from a position between the first light-emitting device 21 and the second light-emitting device 22 that are of the same color and adjacent to each other to the outside of the display apparatus 1000 at least, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

For example, as shown in FIG. 9C, the light shielding portion 40 may be disposed between a first light-emitting device 21 and a second light-emitting device 22 that are of different colors and adjacent to each other.

In this way, light with a large emission angle emitted by the second light-emitting device 22 may be incident on the light shielding portion 40, and the light shielding portion 40 may block and absorb the light with the large emission angle that would have been transmitted from a position between the first light-emitting device 21 and the second light-emitting device 22 that are of different colors and adjacent to each other to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

For example, in the case where the light shielding portions 40 are disposed on two sides of the second light-emitting device 22, as shown in FIG. 9A and FIGS. 10 to 12, the light shielding portions 40 include a first light shielding portion 41 and a second light shielding portion 42 that are respectively located on two sides of the second light-emitting device 22. The first light shielding portion 41 is disposed between the first light-emitting device 21 and the second light-emitting device 22 that are of the same color and adjacent to each other, and the second light shielding portion 42 is disposed between another first light-emitting device 21 and the second light-emitting device 22 that are of different colors and adjacent to each other

In this way, light with a large emission angle emitted by the second light-emitting device 22 may be incident on the first light shielding portion 41 and the second light shielding portion 42, the first light shielding portion 41 may block and absorb light with a large emission angle that would have been transmitted from a position between the first light-emitting device 21 and the second light-emitting device 22 that are of the same color and adjacent to each other to the outside of the display apparatus 1000, and the second light shielding portion 42 may block and absorb light with a large emission angle that would have been transmitted from a position between the first light-emitting device 21 and the second light-emitting device 22 that are of different colors and adjacent to each other to the outside of the display apparatus 1000, so that the range of light emission angle of the second light-emitting device 22 may be greatly narrowed to greatly reduce the light emission angle of the display panel 100 and the display apparatus 1000 in the privacy protection display state. As a result, the privacy protection display effect of the display panel 100 and the display apparatus 1000 is greatly improved.

In some examples, as shown in FIG. 13B, a single light shielding portion 40 may be disposed between multiple first light-emitting devices 21 and multiple second light-emitting devices 22.

The multiple first light-emitting devices 21 may be located on a side of the light shielding portion 40, and the multiple second light-emitting devices 22 may be located on another side of the light shielding portion 40. Alternatively, some of the multiple first light-emitting devices 21 and some of the multiple second light-emitting devices 22 are located on a side of the light shielding portion 40, and some other of the multiple first light-emitting devices 21 and some other of the multiple second light-emitting devices 22 are located on another side of the light shielding portion 40.

In this way, light with a large emission angle emitted by the multiple second light-emitting devices 22 may be incident on the single light shielding portion 40, and the single light shielding portion 40 may block and absorb the light with the large emission angle that would have been transmitted from a position between the multiple first light-emitting devices 21 and the multiple second light-emitting devices 22 to the outside of the display apparatus 1000, so that the single light shielding portion 40 may narrow the ranges of light emission angles of the multiple second light-emitting device 22 to reduce the light emission angle of the display panel 100 and the display apparatus 1000 in the privacy protection display state. As a result, the privacy protection display effect of the display panel 100 and the display apparatus 1000 is improved.

In some examples, as shown in FIGS. 90, 13B and 18B, a single light shielding portion 40 may be disposed between two adjacent second light-emitting devices 22 of different colors.

In this way, light with a large emission angle emitted by the two adjacent second light-emitting devices 22 of different colors may be incident on the light shielding portion 40, and the light shielding portion 40 may block and absorb the light with the large emission angle that would have been transmitted from a position between the two adjacent second light-emitting devices 22 of different colors to the outside of the display apparatus 1000, so that the light shielding portion 40 may narrow the ranges of light emission angles of the two adjacent second light-emitting devices 22 of different colors to reduce the light emission angle of the display panel 100 and the display apparatus 1000 in the privacy protection display state. As a result, the privacy protection display effect of the display panel 100 and the display apparatus 1000 is improved.

In some embodiments, as shown in FIG. 9C, in the first direction X, a distance d between the light shielding portion 40 and a sidewall of the second light-emitting device 22 adjacent to the light shielding portion 40 is less than or equal to 5 μm; for example, the value of d may be 0 μm, 0.5 μm, 1 μm, 1.5 μm, 2 μm, 2.5 μm, 3 μm, 3.5 μm, 4 μm, 4.5 μm or 5 μm.

With the design in which the distance d between the light shielding portion 40 and the sidewall of the second light-emitting device 22 adjacent to the light shielding portion 40 is limited within a small range, most of the light with a large emission angle emitted by the second light-emitting device 22 may be incident on the light shielding portion 40, and the light shielding portion 40 may block and absorb the most of the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some embodiments, as shown in FIG. 9C, an extension direction of the light shielding portion 40 is substantially parallel to an edge of a second light-emitting device 22. An extension length L1 of the light shielding portion 40 is greater than or equal to a length L2 of the edge of the second light-emitting device 22. It will be understood that, in the first direction X, the length L1 of the light shielding portion 40 is greater than or equal to the length L2 of the edge of the second light-emitting device 22.

In this way, light with a large emission angle emitted by the second light-emitting device 22 may be incident on the light shielding portion 40, and the light shielding portion 40 may block and absorb all of the light with the large emission angle that would have been transmitted from the edge of the second light-emitting device 22 parallel to the light shielding portion 40 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some embodiments, in the second direction Y, the light shielding portion 40 may be of a one-piece structure formed by multiple patterning processes. As shown in FIGS. 18A and 21, the step S400 may include step S420 to step S421.

In the step S420, a light shielding sub-portion 43 is formed on the side of the first light blocking portion 30 away from the base substrate 10.

For example, the step S420 may include: forming the light shielding sub-portion 43 on the side of the first light blocking portion 30 away from the base substrate 10 by coating, exposure and development.

For example, a shape of a section of the light shielding sub-portion 43 on the plane parallel to the first direction X may include a rectangle, a trapezoid, a circle, an ellipse, and a polygon.

In the step S421, a plurality of light shielding sub-portions 43 are formed by repeating the step S420 to together constitute the light shielding portion 40, and the plurality of light shielding sub-portion 43 are sequentially stacked in the second direction Y.

A number of times that the coating process, the exposure process, and the development process are performed in the process of forming the light shielding sub-portions 43 may be selected according to a dimension (i.e., a thickness of the light shielding sub-portion 43) in the second direction Y of the light shielding sub-portion 43 and a coating size (i.e., a coating thickness) in the second direction Y of a single coating process. For example, the coating thickness of a single coating process may be 2 μm.

After the step S421, the planarization layer 50 may be formed on the side of the first light blocking portion 30 away from the base substrate 10 by sequentially performing an inkjet printing process and a curing process, and the light shielding portion 40 is located in the planarization layer 50.

In this way, it is possible to form the planarization layer 50 after the light shielding portion 40 is formed.

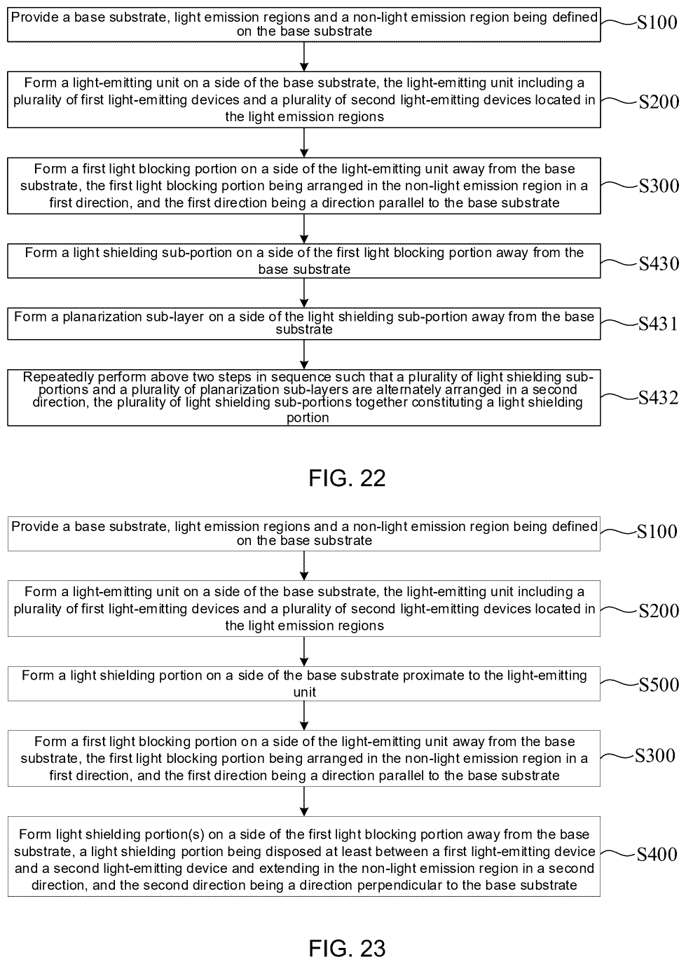

In some other embodiments, as shown in FIGS. 13A and 13B and FIGS. 14 to 16, in the second direction Y, the light shielding portion 40 may be of a split structure, and the light shielding portion 40 may include a plurality of light shielding sub-portions 43, and the plurality of light shielding sub-portion 43 are sequentially arranged in the second direction Y at intervals. As shown in FIG. 22, the step S400 may include step S430 to step S432.

In the step S430, a light shielding sub-portion 43 is formed on the side of the first light blocking portion 30 away from the base substrate 10.

The specific process of forming the light shielding sub-portion 43 in the step S430 may refer to the step S420, which will not be repeated here.

A dimension, in the second direction Y, of the light shielding sub-portion 43 formed in the step S430 may be the same as or different from the dimension, in the second direction Y, of the light shielding sub-portion 43 formed in the step S420, which is not limited here.

For example, a shape of a section of the light shielding sub-portion 43 taken along the first direction X may include a rectangle, a trapezoid, a circle, an ellipse, and a polygon.

In the step S431, a planarization sub-layer is formed on a side of the light shielding sub-portion 43 away from the base substrate 10.

For example, the step S431 may include: forming the planarization sub-layer on the side of the light shielding sub-portion 43 away from the base substrate 10 by sequentially performing an inkjet printing process and a curing process.

In the step S432, the above step S430 and the step S431 are repeated in sequence such that a plurality of light shielding sub-portions 43 and a plurality of planarization sub-layers are alternately arranged in the second direction Y; the plurality of light shielding sub-portion 43 together constitute the light shielding portion 40, and the plurality of planarization sub-layers together constitute the planarization layer 50.

For example, in the second direction Y, a dimension d1 (i.e., a thickness of the light shielding sub-portion 43) of the light shielding sub-portion 43 may be greater than or equal to 1 μm and less than or equal to 5 μm; for instance, the thickness of the light shielding sub-portion 43 may be 1 μm, 1.5 μm, 2 μm, 2.5 μm, 3 μm, 3.5 μm, 4 μm, 4.5 μm or 5 μm.

For example, the thickness d1 of the light shielding sub-portion 43 and a dimension (i.e., a thickness of the planarization sub-layer) of the planarization sub-layer in the second direction Y may be the same or different, which is not limited here.

In this way, in a case where light with a large emission angle emitted by the second light-emitting device 22 is incident on the plurality of light shielding sub-portions 43, the plurality of light shielding sub-portions 43 may block and absorb the light with the large emission angle that would have been transmitted to the outside of the display apparatus 1000, which may narrow the range of light emission angle of the second light-emitting device 22 to reduce the light emission angles of the display panel 100 and the display apparatus 1000 in the privacy protection display state, thereby improving the privacy protection display effect of the display panel 100 and the display apparatus 1000. On the basis of the improvement of the privacy protection display effect of the display panel 100 and the display apparatus 1000, the plurality of light shielding sub-portions 43 may also reduce the blocking and absorption of the light for displaying images emitted by the first light-emitting device 21, thereby ensuring the screen sharing display effect of the display panel 100 and the display apparatus 1000.

In some examples, as shown in FIG. 13A, in the second direction Y, a distance d2 between two adjacent light shielding sub-portions 43 may be greater than or equal to 1.5 μm and less than or equal to 15 μm. For example, the distance d2 between two adjacent light shielding sub-portions 43 may be 1.5 μm, 2 μm, 3 μm, 5 μm, 7 μm, 8 μm, 9 μm, 10 μm, 12 μm, 14 μm or 15 μm. The distance d2 between two adjacent light shielding sub-portions 43 and the thickness d1 of the light shielding sub-portion 43 may be the same or different, which is not limited here.

On the basis that the plurality of light shielding sub-portions 43 may improve the privacy protection display effect of the display panel 100 and the display apparatus 1000, the distance d2 between two adjacent light shielding sub-portions 43 is limited within a proper range, which may greatly reduce the blocking and absorption of the light for displaying images emitted by the first light-emitting device 21 by the plurality of light shielding sub-portions 43, thereby well ensuring the screen sharing display effect of the display panel 100 and the display apparatus 1000.

In some embodiments, as shown in FIG. 23, the manufacturing method may further include a step S500 after the step S200.

In the step S500, light shielding portion(s) 40 is formed on a side of the base substrate 10 proximate to the light-emitting unit 20. Here, the step S500 may be understood as that a portion of a light shielding portion 40 is formed on the side of the base substrate 10 proximate to the light-emitting unit 20 after the step S200 and before the step S300, and another portion of the light shielding portion 40 is formed on the side of the first light blocking portion 30 away from the base substrate 10 in the step S400.

In some examples, as shown in FIG. 10, in the second direction Y, the light shielding portion 40 may be of a one-piece structure formed by a single patterning process.

For example, the step S500 may include: forming at least one second through hole 46 extending in the second direction Y in the encapsulation layer TFE. The second through hole 46 is disposed at least between the first light-emitting device 21 and the second light-emitting device 22.

For example, the second through hole 46 may extend in the second direction Y from the first light blocking portion 30 into the second inorganic layer TFE3 of the encapsulation layer TFE. For another example, the second through hole 46 may extend in the second direction Y from the first light blocking portion 30 into the second inorganic layer TFE3 and the organic layer TFE2 of the encapsulation layer TFE. For still another example, the second through hole 46 may extend in the second direction Y from the first light blocking portion 30 into the entire encapsulation layer TFE.

An orthogonal projection of an outer contour of the second through hole 46 on the base substrate 10 at least partially overlaps with an orthographic projection of an outer contour of the first through hole 45 on the base substrate 10. It will be understood that, the orthogonal projection of the outer contour of the second through hole 46 on the base substrate 10 partially overlaps with the orthographic projection of the outer contour of the first through hole 45 on the base substrate 10, or the orthogonal projection of the outer contour of the second through hole 46 on the base substrate 10 completely overlaps with the orthographic projection of the outer contour of the first through hole 45 on the base substrate 10.

A shape of a section of the second through hole 46 taken along the first direction X may be the same as or different from the shape of the section of the first through hole 45 taken along the first direction X, which is not limited here.

The relative positional relationship between the second through hole 46 and the light-emitting devices may be the same as the relative positional relationship between the first through hole 45 and the light-emitting devices, and will not be elaborated here.

After the second through hole 46 is formed, the light shielding portion 40 is formed in the second through hole 46.

In some examples, in the case where the light shielding portion 40 is located on one side of the first light blocking portion 30, the light shielding portion 40 may extend in the second direction Y from the first light blocking portion 30 into the encapsulation layer TFE.

In some other examples, in the case where the light shielding portion 40 is located on two sides of the first light blocking portion 30, as shown in FIGS. 10 and 14, the light shielding portion 40 may extend in the second direction Y from the planarization layer 50 into the encapsulation layer TFE.

For example, the light shielding portion 40 may extend in the second direction Y from the planarization layer 50 into the second inorganic layer TFE3 of the encapsulation layer TFE. For another example, the light shielding portion 40 may extend in the second direction Y from the planarization layer 50 into the second inorganic layer TFE3 and the organic layer TFE2 of the encapsulation layer TFE. For still another example, the light shielding portion 40 may extend in the second direction Y from the planarization layer 50 into the entire encapsulation layer TFE.

In this way, light with a large emission angle emitted by the second light-emitting device 22 may be incident on the light shielding portion 40 in the encapsulation layer TFE, and the light shielding portion 40 may block and absorb the light with the large emission angle that would have been transmitted through the encapsulation layer TFE to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000

For example, as shown in FIGS. 11 and 17, the step S500 may include: forming the at least one second through hole 46 extending in the second direction Y in the encapsulation layer TFE and the pixel defining layer PDL. A second through hole 46 is disposed at least between the first light-emitting device 21 and the second light-emitting device 22. After the second through hole 46 is formed, the light shielding portion 40 is formed in the second through hole 46.

In some examples, in the case where the light shielding portion 40 is located on one side of the first light blocking portion 30, the pixel defining layer PDL may be made of a semi-transmissive material, and the light shielding portion 40 may extend in the second direction Y from the first light blocking portion 30 into the pixel defining layer PDL.

In some other examples, in the case where the light shielding portion 40 is located on two sides of the first light blocking portion 30, the pixel defining layer PDL may be made of a semi-transmissive material, and as shown in FIGS. 11, 15 and 17, and the light shielding portion 40 may extend in the second direction Y from the planarization layer 50 into the pixel defining layer PDL.

In this way, light with a large emission angle emitted by the second light-emitting device 22 may be incident on the light shielding portion 40 in the pixel defining layer PDL, and the light shielding portion 40 in the pixel defining layer PDL may completely block and absorb the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, in the case where the light shielding portion 40 is located on one side of the first light blocking portion 30, the pixel defining layer PDL may be made of a black light-blocking material, and the light shielding portion 40 may extend in the second direction Y from the first light blocking portion 30 to a surface of the pixel defining layer PDL away from the base substrate 10.

In some other examples, in the case where the light shielding portion 40 is located on two sides of the first light blocking portion 30, the pixel defining layer PDL may be made of a black light-blocking material, and as shown in FIGS. 12 and 16, the light shielding portion 40 may extend in the second direction Y from the planarization layer 50 to the surface of the pixel defining layer PDL away from the base substrate 10.

In this way, light with a large emission angle emitted by the second light-emitting device 22 may be incident on the pixel defining layer PDL and the light shielding portion 40, and the pixel defining layer PDL and the light shielding portion 40 may block and absorb the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some examples, as shown in FIG. 10, in the second direction Y, the light shielding portion 40 may be of a one-piece structure formed by multiple patterning processes.

The step S500 may include the following steps. A light shielding sub-portion 43 is formed on a side of the light-emitting unit 20 away from the base substrate 10 by coating, exposure and development.

Then, a plurality of light shielding sub-portions 43 that are sequentially stacked in the second direction Y are formed by repeatedly performing the coating process, the exposure process and the development process in sequence, so that the plurality of light shielding sub-portions 43 together constitute the light shielding portion 40.

Then, an encapsulation layer TFE is formed on a side of the light-emitting unit 20 away from the base substrate 10 by deposition. The light shielding portion 40 is embedded in the encapsulation layer TFE, and an interface between the light shielding portion 40 and the encapsulation layer TFE is sealed, so that the interface between the light shielding portion 40 and the encapsulation layer TFE has a sealing effect and can block water and oxygen.

In this way, in a case where light with a large emission angle emitted by the second light-emitting device 22 is incident on the light shielding portion 40 in the encapsulation layer TFE, the light shielding portion 40 may block and absorb the light with the large emission angle that would have been transmitted to the outside of the display apparatus 1000 through the encapsulation layer TFE, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000.

In some other examples, as shown in FIG. 14, in the second direction Y, the light shielding portion 40 may be of a split structure. The light shielding portion 40 may include a plurality of light shielding sub-portions 43, and the plurality of light shielding sub-portions 43 are sequentially arranged in the second direction Y at intervals.

The step S500 may refer to the step S430 to step S432, which will not be elaborated here.

In this way, light with a large emission angle emitted by the second light-emitting device 22 may be incident on the plurality of light shielding sub-portions 43, and the plurality of light shielding sub-portions 43 may block and absorb the light with the large emission angle that would have been transmitted to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000. On the basis of the improvement of the privacy protection display effect of the display panel 100 and the display apparatus 1000, the plurality of light shielding sub-portions 43 may also reduce the blocking and absorption of the light for displaying images emitted by the first light-emitting device 21, thereby ensuring the screen sharing display effect of the display panel 100 and the display apparatus 1000.

In summary, in the display panel 100 manufactured by the manufacturing method for the display panel 100 provided by the embodiments of the present disclosure, light with a large emission angle emitted by the second light-emitting device 22 may be incident on the first light blocking portion 30 and the light shielding portion 40, and the first light blocking portion 30 and the light shielding portion 40 may block and absorb the light with the large emission angle that would have been transmitted from the second light-emitting device 22 to the outside of the display apparatus 1000, which may narrow the range of light emission angle of the second light-emitting device 22 to reduce the light emission angle of the display panel 100 and the display apparatus 1000 in the privacy protection display state, thereby improving the privacy protection display effect of the display panel 100 and the display apparatus 1000. Furthermore, the first light blocking portion 30 may also prevent light of different colors emitted from other light emission regions EA from entering a certain light emission region EA, so as to ensure the color purity of the light emitted from each light emission region EA and improve the color contrast of the light emitted from each light emission region EA. As a result, the display effect of the display panel 100 and the display apparatus 1000 is improved.

The above are merely specific embodiments of the present disclosure, but the protection scope of the present disclosure is not limited thereto, and variations or substitutions that a person skilled in the art could conceive of within the technical scope of the present disclosure should all fall within the protection scope of the present disclosure. Therefore, the protection scope of the present disclosure should be subjected to the protection scope of the claims.

1. A display panel, comprising:
a base substrate including light emission regions and a non-light emission region;
a light-emitting unit located on a side of the base substrate, wherein the light-emitting unit includes a plurality of first light-emitting devices and a plurality of second light-emitting devices that are located in the light emission regions;
a first light blocking portion located on a side of the light-emitting unit away from the base substrate and arranged in the non-light emission region in a first direction, wherein the first direction is a direction substantially parallel to the base substrate; and
least one light shielding portion located at least on a side of the first light blocking portion away from the base substrate, wherein a light shielding portion of the at least one light shielding portion is disposed at least between a first light-emitting device of the plurality of first light-emitting devices and a second light-emitting device of the plurality of second light-emitting devices and extends in the non-light emission region in a second direction; the second direction is a direction substantially perpendicular to the base substrate.

2. The display panel according to claim 1, wherein the light shielding portion is disposed at least between the first light-emitting device and the second light-emitting device that are of a same color and adjacent to each other.

3. The display panel according to claim 1, wherein the at least one light shielding portion includes a plurality of light shielding portions, and the plurality of light shielding portions include a first light shielding portion and a second light shielding portion that are respectively located on two sides of the second light-emitting device;
the first light shielding portion is disposed between a first light-emitting device and a second light-emitting device that are of a same color and adjacent to each other, and the second light shielding portion is disposed between another first light-emitting device and the second light-emitting device that are of different colors and adjacent to each other.

4. The display panel according to claim 1, wherein a light shielding portion of the at least one light shielding portion includes a plurality of light shielding sub-portions; the plurality of light shielding sub-portions are sequentially arranged in the second direction at intervals.

5. The display panel according to claim 4, wherein in the second direction, a distance between two adjacent light shielding sub-portions is greater than or equal to 1.5 μm and less than or equal to 15 μm.

6. The display panel according to claim 1, wherein in the first direction, a distance between the light shielding portion and a sidewall of the second light-emitting device adjacent to the light shielding portion is less than or equal to 5 μm.

7. The display panel according to claim 1, wherein an extension direction of the light shielding portion is substantially parallel to an edge of the second light-emitting device, and an extension length of the light shielding portion is greater than or equal to a length of the edge of the second light-emitting device.

8. The display panel according to claim 1, wherein a light shielding portion of the at least one light shielding portion is disposed between multiple first light-emitting devices of the plurality of first light-emitting devices and multiple second light-emitting devices of the plurality of second light-emitting devices;
wherein the multiple first light-emitting devices are located on a side of the light shielding portion, and the multiple second light-emitting devices are located on another side of the light shielding portion.

9. The display panel according to claim 1, wherein a light shielding portion of the at least one light shielding portion extends in the second direction toward a side of the first light blocking portion proximate to the base substrate.

10. The display panel according to claim 1, further comprising:
a second light blocking portion located on the side of the first light blocking portion away from the base substrate, wherein an orthographic projection of the second light blocking portion on the base substrate abuts an orthographic projection of the light shielding portion on the base substrate.

11. The display panel according to claim 10, wherein the second light blocking portion is disposed on a side of the second light-emitting device in the first direction, and a light shielding portion of the at least one light shielding portion is disposed on another side of the same second light-emitting device in the first direction.

12. The display panel according to claim 10, wherein the orthographic projection of the second light blocking portion on the base substrate partially overlaps with an orthographic projection of the second light-emitting device adjacent to the second light blocking portion on the base substrate; and
an orthographic projection of a portion of the first light blocking portion that is located in a same portion of the non-light emission region as the second light blocking portion is non-overlapping with the orthographic projection of the same second light-emitting device on the base substrate.

13. The display panel according to claim 1, further comprising:
color filters located on the side of the light-emitting unit away from the base substrate, wherein the color filters include a first color filter and a second color filter; the first color filter covers the first light-emitting device, and the second color filter covers the second light-emitting device; in the first direction, a dimension of the first color filter is greater than a dimension of the first light-emitting device, and a dimension of the second color filter is greater than a dimension of the second light-emitting device.

14. A manufacturing method for a display panel, comprising:
providing a base substrate, wherein light emission regions and a non-light emission region are defined on the base substrate;
forming a light-emitting unit on a side of the base substrate, wherein the light-emitting unit includes a plurality of first light-emitting devices and a plurality of second light-emitting devices located in the light emission regions;
forming a first light blocking portion on a side of the light-emitting unit away from the base substrate, wherein the first light blocking portion is arranged in the non-light emission region in a first direction; the first direction is a direction parallel to the base substrate; and
forming at least one light shielding portion on a side of the first light blocking portion away from the base substrate, wherein a light shielding portion of the at least one light shielding portion is disposed at least between a first light-emitting device of the plurality of first light-emitting devices and a second light-emitting device of the plurality of second light-emitting devices and extends in the non-light emission region in a second direction; the second direction is a direction perpendicular to the base substrate.

15. The manufacturing method for the display panel according to claim 14, wherein after forming the light-emitting unit on the side of the base substrate and before forming the first light blocking portion on the side of the light-emitting unit away from the base substrate, the manufacturing method further comprises:
forming a portion of the light shielding portion on a side of the base substrate proximate to the light-emitting unit, wherein
forming the at least one light shielding portion on the side of the first light blocking portion away from the base substrate includes: forming another portion of the light shielding portion on the side of the first light blocking portion away from the base substrate.

16. The manufacturing method for the display panel according to claim 14, wherein forming the light shielding portion on the side of the first light blocking portion away from the base substrate includes:
forming a planarization layer on a side of the first light blocking portion away from the base substrate;
forming at least one first through hole extending in the second direction in the planarization layer, wherein a first through hole of the at least one first through hole is disposed at least between the first light-emitting device and the second light-emitting device; and
forming a light shielding portion in the first through hole.

17. The manufacturing method for the display panel according to claim 14, wherein forming the light shielding portion on the side of the first light blocking portion away from the base substrate includes:
forming a light shielding sub-portion on the side of the first light blocking portion away from the base substrate; and
repeatedly performing the step of forming a light shielding sub-portion on the side of the first light blocking portion away from the base substrate such that a plurality of light shielding sub-portions together constitute the light shielding portion, wherein the plurality of light shielding sub-portions are sequentially stacked in the second direction.

18. The manufacturing method for the display panel according to claim 14, wherein forming the light shielding portion on the side of the first light blocking portion away from the base substrate includes:
forming a light shielding sub-portion on the side of the first light blocking portion away from the base substrate;
forming a planarization sub-layer on a side of the light shielding sub-portion away from the base substrate; and
repeatedly performing the two steps of forming a light shielding sub-portion on the side of the first light blocking portion away from the base substrate and forming a planarization sub-layer on the side of the light shielding sub-portion away from the base substrate in sequence such that a plurality of light shielding sub-portions and a plurality of planarization sub-layers are alternately arranged in the second direction, wherein the plurality of light shielding sub-portion together constitute the light shielding portion.

19. A display apparatus, comprising:
a circuit board; and
the display panel according to claim 1, wherein the display panel is located on a side of the circuit board and coupled to the circuit board.

20. The display panel according to claim 1, further comprising:
a pixel defining layer located on a side of the base substrate proximate to the light-emitting unit; wherein the pixel defining layer includes a plurality of light emission openings, the plurality of first light-emitting devices and the plurality of second light-emitting devices cover the plurality of light emission openings, and a material of the pixel defining layer is a black light-blocking material.
